(19) United States
(12) Patent Application Publication
(10) Pub. No.: US 2026/0057161 A1
(43) Pub. Date: Feb. 26, 2026

(54) Systems and Methods for a Recursive Document Splitting and Chunking System for FPGA Documentation and Tool Reports

(71) Applicants: Saurabh Kotiyal, San Jose, CA (US); Mahesh A. Iyer, Fremont, CA (US); Nabeel Shirazi, Saratoga, CA (US)

(72) Inventors: Saurabh Kotiyal, San Jose, CA (US); Mahesh A. Iyer, Fremont, CA (US); Nabeel Shirazi, Saratoga, CA (US)

(21) Appl. No.: 19/376,452

(22) Filed: Oct. 31, 2025

(51) Int. Cl. G06F 30/347

(52) U.S. Cl. CPC G06F 30/347

(57) ABSTRACT

Systems or methods of the present disclosure may provide a design tool for adjusting designs implemented on programmable logic devices. The present disclosure includes receiving one or more data tables and receiving one or more design files. The one or more data tables may include technical specifications, user guides, and/or best practices. The one or more design files may include design inputs and design outputs such as timing reports, design assistant/rule violation (DRC) reports, and/or log files. The present disclosure also includes determining one or more chunks based on the one or more data tables, generating one or more embeddings based on the one or more chunks, extracting data from the one or more design files, while considering contextual information, natural break points, and cross-referencing. Furthermore, the present disclosure includes providing the one or more embeddings and the data to a large language model (LLM).

### BACKGROUND

The present disclosure relates generally to integrated circuits, such as field-programmable gate arrays and/or programmable logic devices. More particularly, the present disclosure relates to a design assistant tool (e.g., QuartusPilot™) for integrated circuits.

Programmable logic devices, a class of integrated circuits, may be programmed to perform a wide variety of operations. For example, the programmable logic devices may implement and edit designs using design tools. However, as programmable logic devices increase in complexity and/or increase in size, the designs of the programmable logic devices may also become more complex. For example, integrated circuits designers may reference a large number of resources in a design process. Yet many design tools may provide assistance with results with mistakes or with unintelligible results.

### BRIEF DESCRIPTION OF THE DRAWINGS

Various aspects of this disclosure may be better understood upon reading the following detailed description and upon reference to examples shown in the drawings in which:

FIG. 1 is a block diagram of a system used to program an integrated circuit;

FIG. 2 is a block diagram of an example of the integrated circuit of FIG. 1;

FIG. 3 is an illustration of a compilation dashboard associated with the integrated circuit of FIG. 1;

FIG. 4 is a screen capture of a graphical user interface (GUI) generated by a design assistant used to design the integrated circuit of FIG. 1;

FIG. 5 is a screen capture of the GUI of FIG. 4 including an example of a user prompt regarding issues with a design;

FIG. 6 is a screen capture of the GUI of FIG. 4 including an example of another user prompt regarding issues with the design;

FIG. 7 is a screen capture of the GUI of FIG. 4 including an analysis of the issues with the design;

FIG. 8 is a screen capture of the GUI of FIG. 4 including an example of a follow up user prompt regarding issues with the design;

FIG. 9 is a screen capture of the GUI of FIG. 4 including an example of a user prompt regarding timing paths in the design;

FIG. 10 is a screen capture of the GUI of FIG. 4 including an analysis of the timing paths in the design;

FIG. 11 is a screen capture of the GUI of FIG. 4 including an explanation of implementation of a suggestion regarding the timing paths in the design;

FIG. 12 is a screen capture of the GUI of FIG. 4 including another explanation of the implementation of the suggestion regarding the timing paths in the design;

FIG. 13 is a screen capture of the GUI of FIG. 4 including the implementation of the suggestion regarding the timing paths in the design;

FIG. 14 is a screen capture of the GUI of FIG. 4 including implementation of adding pipeline in the design;

FIG. 15 is a block diagram of an example of the design assistant used to design the integrated circuit of FIG. 1;

FIG. 16 is a block diagram of a context-aware retrieval system of the design assistant of FIG. 15;

FIG. 17 is an illustration of an example of a FPGA documentation index associated with the design assistant of FIG. 15;

FIG. 18 is an illustration of an example of violation internal knowledge associated with the design assistant of FIG. 15;

FIG. 19 is an illustration of an example of message internal knowledge associated with the design assistant of FIG. 15;

FIG. 20 is a screen capture of example designs associated with the design assistant of FIG. 15;

FIG. 21 is an illustration of an example of device documentation associated with the design assistant of FIG. 15;

FIG. 22 is an illustration of example of IP catalog data associated with the design assistant of FIG. 15;

FIG. 23 is a screen capture of an example of documentation used in a documentation embedding creation associated with the design assistant of FIG. 15;

FIG. 24 is a flowchart of an example method for specialized data indexing of the context-aware retrieval system of FIG. 16;

FIG. 25 is a flowchart of an example method for context-aware embedding of the context-aware retrieval system of FIG. 16;

FIG. 26 is a flowchart of an example method for an intelligent retrieval system of the context-aware retrieval system of FIG. 16;

FIG. 27 is a flowchart of an example method for workflow integration of the context-aware retrieval system of FIG. 16;

FIG. 28 is a flowchart of an example method for the context-aware retrieval system of FIG. 16;

FIG. 29 is a block diagram of a recursive document splitting and chunking system of the design assistant of FIG. 15;

FIG. 30 is a screen capture of an example of a report file used in a design data embedding creation associated with the design assistant of FIG. 15;

FIG. 31 is a screen capture of an example of an embedding generation associated with the design assistant of FIG. 15;

FIG. 32 is an illustration of an example of a data table associated with the design assistant of FIG. 15;

FIG. 33 is a flowchart of an example method for FPGA-aware document analysis of the recursive document splitting and chunking system of FIG. 29;

FIG. 34 is a flowchart of an example method for a recursive splitting algorithm of the recursive document splitting and chunking system of FIG. 29;

FIG. 35 is a flowchart of an example method for a context preservation system of the recursive document splitting and chunking system of FIG. 29;

FIG. 36 is an illustration of an example of a table chunking relationship associated with the design assistant of FIG. 15;

FIG. 37 is a flowchart of an example method for integration with RAG systems of the recursive document splitting and chunking system of FIG. 29;

FIG. 38 is a flowchart of an example method for the recursive document splitting and chunking system of FIG. 29;

FIG. 39 is a block diagram of a FPGA design history integration system of the design assistant of FIG. 15;

FIG. 40 is a screen capture of an example of historical data collection associated with the design assistant of FIG. 15;

FIG. 41 is an illustration of an example of a design evolution associated with the design assistant of FIG. 15;

FIG. 42 is a flowchart of an example method for historical data tracking of the FPGA design history integration system of FIG. 39;

FIG. 43 is a flowchart of an example method for a pattern recognition system of the FPGA design history integration system of FIG. 39;

FIG. 44 is a flowchart of an example method for a natural language interface of the FPGA design history integration system of FIG. 39;

FIG. 45 is a flowchart of an example method for the FPGA design history integration system of FIG. 39;

FIG. 46 is a block diagram of a dynamic scoping system of the design assistant of FIG. 15;

FIG. 47 is a flowchart of an example method for a scope analysis system of the dynamic scoping system of FIG. 46;

FIG. 48 is a screen capture of an example of slash commands associated with the design assistant of FIG. 15;

FIG. 49 is a flowchart of an example method for command processing of the dynamic scoping system of FIG. 46;

FIG. 50 is a flowchart of an example method for file type management of the dynamic scoping system of FIG. 46;

FIG. 51 is a flowchart of an example method for a context-aware search of the dynamic scoping system of FIG. 46;

FIG. 52 is a flowchart of an example method for the dynamic scoping system of FIG. 46;

FIG. 53 is a block diagram of a cross-referencing system of the design assistant of FIG. 15;

FIG. 54 is a screen capture of an example of cross referencing design software (e.g., Quartus®) data associated with the design assistant of FIG. 15;

FIG. 55 is a screen capture of an example of cross referencing documentation data sources associated with the design assistant of FIG. 15;

FIG. 56 is a screen capture of an example of relevant references associated with the design assistant of FIG. 15;

FIG. 57 is a flowchart of an example method for a cross-reference engine of the cross-referencing system of FIG. 53;

FIG. 58 is a flowchart of an example method for a source attribution system of the cross-referencing system of FIG. 53;

FIG. 59 is a flowchart of an example method for a knowledge integration system of the cross-referencing system of FIG. 53;

FIG. 60 is a flowchart of an example method for context-aware visualization of the cross-referencing system of FIG. 53;

FIG. 61 is a flowchart of an example method for the cross-referencing system of FIG. 53;

FIG. 62 is a screen capture of an example of MCP tools within the MCP based agent system of the design assistant of FIG. 15;

FIG. 63 is a screen capture of an example of a sample query using an MCP server associated with the design assistant of FIG. 15;

FIG. 64 is an illustration of an example of a design software (e.g., Quartus® Copilot) architecture associated with the design assistant of FIG. 15;

FIG. 65 is an illustration of an example of an MCP architecture associated with the design assistant of FIG. 15;

FIG. 66 is a flowchart of an example method for MCP architecture framework of the MCP based agent system of FIG. 62;

FIG. 67 is a flowchart of an example method for a documentation agent of the MCP based agent system of FIG. 62;

FIG. 68 is a flowchart of an example method for an IP catalog agent of the MCP based agent system of FIG. 62;

FIG. 69 is a flowchart of an example method for an IP parameter agent of the MCP based agent system of FIG. 62;

FIG. 70 is a flowchart of an example method for an IP interface agent of the MCP based agent system of FIG. 62;

FIG. 71 is a flowchart of an example method for a project analysis agent of the MCP based agent system of FIG. 62;

FIG. 72 is a flowchart of an example method for a report analysis agent of the MCP based agent system of FIG. 62;

FIG. 73 is a flowchart of an example method for an RTL validation agent of the MCP based agent system of FIG. 62;

FIG. 74 is a flowchart of an example method for the MCP based agent system of FIG. 62;

FIG. 75 is a flowchart of an example method for a context preservation system of the MCP based agent system of FIG. 62;

FIG. 76 is a flowchart of an example method for an agent coordination framework of the MCP based agent system of FIG. 62;

FIG. 77 is a flowchart of an example method for an extensibility framework of the MCP based agent system of FIG. 62; and

FIG. 78 is a block diagram of a data processing system including the integrated circuit of FIG. 1.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

The present disclosure describes systems and techniques related to using a design tool (e.g., a design assistant) to generate and implement designs onto integrated circuit devices, such as field-programmable gate arrays (FPGAs) or application-specific integrated circuits (ASICs), to improve design decisions (e.g., decrease design errors). For example, the design tool may generate a graphical user interface (GUI) including different views of a design that may be implemented onto the programmable logic device, and a display may display the GUI. As such, a user (e.g., designer) may quickly visualize all components of the design. The user may interact with the design tool to ask a question regarding the design. The design tool may update the GUI based on inputs indicative of adjusting the design. For example, the user may perform design analysis using the design tool and adjust the design based on the analysis. The present disclosure may be applicable to any artificial intelligence (AI) assisted design assistant in the semiconductor industry, including those that may not have field-programmable gate array (FPGA) logic circuitry. The design tool thus may allow any suitable integrated circuit system design to be developed, including those for application-specific integrated circuits (ASICs) (e.g., customized integrated circuits, microprocessors, controllers). Therefore, while the present disclosure may focus on FPGAs, the design tool may also be applicable for ASICs, custom processors, etc.

The design tool may facilitate the design process for the user. For example, the design tool may identify design errors within the integrated circuit and the like. Additionally, or alternatively, the design tool may suggest areas for the user to focus on to identify issues within the design based on provided documentation. In other examples, the design tool may identify issues in the design and provide a recommendation in response. As such, the design tool may facilitate visualization of the design including suggested changes, which may optimize the design for the programmable logic device. For example, the design tool may output FPGA design and device specific suggestions. In some embodiments, the design tool may output information related to standard cells in ASIC libraries, routing track information, metal layers used, etc.

The design tool may provide design context and/or reference documentation that may be helpful to users during the designing process and, by specific example, helpful for optimizing the design. For example, the design tool may provide specific improvements to the design for users to review. The context information may include information associated with the referenced documentation and so on. As such, the design tool may increase productivity by significantly shifting decisions to an earlier point in a design cycle of the programmable logic device in comparison to previous design cycles.

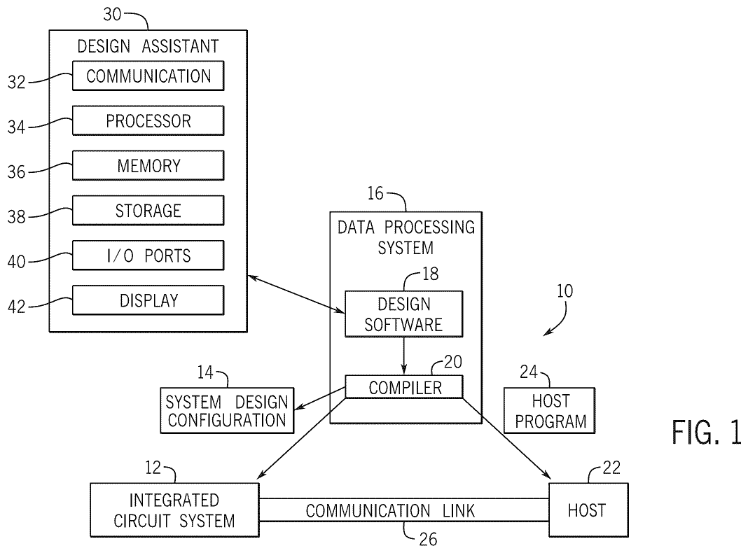

With the foregoing in mind, FIG. 1 illustrates a block diagram of a system 10 that may be used to program an integrated circuit device 12, such as an FPGA (e.g., Agilex™, Stratix®, Arria®, MAX®, or Cyclone® devices by Altera® Corporation), with such a system design using a system design configuration 14. Note that, while this disclosure largely refers to the integrated circuit device 12 as being a programmable logic device, such as an FPGA, in some embodiments, the integrated circuit device 12 may also include a one-time programmable device or structured application specific integrated circuit (ASIC), such as an Intel® eASIC™ device by Intel® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit device 12.

Additionally or alternatively, the host 22 running the host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

In some embodiments, the system 10 may include a design assistant 30 (e.g., QuartusPilot™ by Altera Corporation). In certain embodiments, the design assistant 30 may be communicatively coupled to the design software 18. As illustrated, the design assistant 30 may be located remotely (e.g., in a cloud computing environment). Additionally or alternatively, the design assistant 30 may run locally on a local electronic device (e.g., on the data processing system 16). In some embodiments, the design assistant 30 may include a communication component 32, a processor 34 (e.g., processing circuitry), a memory 36, a storage 38, input/output (I/O) ports 40, a display 42, and the like. It should be understood that the design assistant 30 may include additional or fewer components.

The communication component 32 may be a wireless or wired communication component that may facilitate communication between the design assistant 30 and various other computing systems and devices via a network, the Internet, or the like. For example, the communication component 32 may allow the design assistant 30 to obtain data from a variety of data sources, such as the design software 18, the data processing system 16, or any suitable storage component.

The processor 34 may process instructions for execution within the design assistant 30. The processor 34 may include single-threaded processor(s), multi-threaded processor(s), or both. The processor 34 may process instructions stored in the memory. The processor 34 may also include hardware-based processor(s) each including one or more cores. The processor 34 may include general purpose processor(s), special purpose processor(s), or both. The processor 34 may be communicatively coupled to other internal components (such as the communication component 32, the storage 38, the I/O ports 40, and the display 42).

The memory 36 and the storage 38 may be any suitable articles of manufacture that can serve as media to store processor-executable code, data, or the like. These articles of manufacture may represent computer-readable media (e.g., any suitable form of memory or storage) that may store the processor-executable code used by the processor 34 to perform the presently disclosed techniques. As used herein, applications may include any suitable computer software or program that may be installed onto the design assistant 30 and executed by the processor 34. The memory 36 and the storage 38 may represent non-transitory computer-readable media (e.g., any suitable form of memory or storage) that may store the processor-executable code used by the processor to perform various techniques described herein. It should be noted that non-transitory merely indicates that the media is tangible and not a signal.

The I/O ports 40 may be interfaces that may be coupled to other peripheral components such as input devices (e.g., keyboard, mouse, microphone, speaker), sensors, input/output (I/O) modules, and the like. The display 42 may operate as a human machine interface (HMI) to depict visualizations associated with software or executable code being processed by the processor 34. In one embodiment, the display 42 may be a touch display capable of receiving inputs from an operator of the design assistant 30. The display 42 may be any suitable type of display, such as a liquid crystal display (LCD), plasma display, or an organic light emitting diode (OLED) display, for example. Additionally, in one embodiment, the display 42 may be provided in conjunction with a touch-sensitive mechanism (e.g., a touch screen) that may function as part of a control interface for the design assistant 30.

In some embodiments, the designer (e.g., user) may use the design software 18 to generate and/or to specify a low-level program, such as the low-level hardware description languages described above. Further, in certain embodiments, the system 10 may be implemented without the host program 24. Thus, embodiments described herein are intended to be illustrative and not limiting.

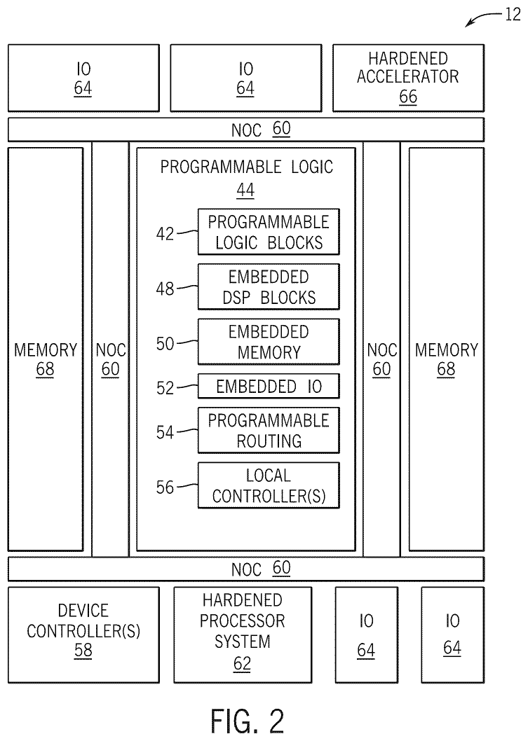

The integrated circuit device 12 may take any suitable form that may implement the system design configuration 14. For example, the integrated circuit device 12 may be an application-specific integrated circuit (ASIC) having the system design configuration 14 as hardened logic circuitry and the design software 18 and compiler 20 may include any suitable software that may provide an ASIC or other hardened system design configuration 14. In this example, the system design configuration 14 may be implemented on the integrated circuit device 12 as the ASIC by any suitable lithography or other manufacturing techniques. In another example, the integrated circuit device 12 may be a programmable logic device (PLD) such as a field programmable gate array (FPGA) and the design software 18 and compiler 20 may include any suitable software that may provide an FPGA system design configuration 14, as shown in one example shown of FIG. 2. In FIG. 2, the integrated circuit device 12 may include programmable logic circuitry 40, which include a two-dimensional array of many different functional blocks, such as programmable logic blocks 42, embedded digital signal processing (DSP) blocks 44, embedded memory blocks 46, and embedded input-output blocks 48. In many cases, there may be rows or columns of these functional blocks that may be programmably connected to one another using programmable routing 50.

The programmable logic blocks 42 may be programmed to implement a wide variety of logic circuitry. The programmable logic blocks 42 may include a number of adaptive logic modules (ALMs), which may take the form of lookup tables (LUTs) that can be programmed to implement a logic truth table, effectively enabling any of the programmable logic blocks 42 to implement any desired logic circuitry when configured with the system design configuration 14. In addition, the ALMs may include registers and/or carry chain adder chains. The programmable logic blocks 42 and are sometimes referred to as logic array blocks (LABs) or configurable logic blocks (CLBs).

The embedded DSP blocks 44, embedded memory blocks 46, and embedded IO blocks 48 may be distributed around the programmable logic blocks 42. For example, there may be several columns of programmable logic blocks 42 for every column of DSP blocks 44, column of embedded memory blocks 46, or column of embedded IO blocks 48. The embedded DSP blocks 44 may include “hardened” circuits that are specialized to efficiently perform certain arithmetic operations. This is in contrast to “soft logic” circuits that may be programmed into the programmable logic blocks 42 to perform the same functions, but which may not be as efficient as the hardened circuits of the DSP blocks 44. The embedded memory blocks 46 may include dedicated local memory (e.g., blocks of 20 kB, blocks of 1 MB). The embedded IO blocks 48 may allow for inter-die or inter-package communication. The embedded DSP blocks 44, embedded memory blocks 46, and embedded IO blocks 48 may be accessible to the programmable logic blocks 42 using the programmable routing 50.

The various functional blocks of the programmable logic circuitry 40 may be grouped into programmable regions, sometimes referred to as logic sectors, that may be individually managed and configured by corresponding local controllers 52 (e.g., sometimes referred to as Local Sector Managers (LSMs)). The grouping of the programmable logic circuitry 40 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 40 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these. In some embodiments, a configuration (e.g., the system design configuration 14) may change CRAM bits, which may impact routing, LUTs, and DSP blocks.

A device controller 54, sometimes referred to as a secure device manager (SDM), may manage the operation of the integrated circuit device 12. The device controller 54 may include any suitable logic circuitry to control and/or program the programmable logic circuitry 40 or other elements of the integrated circuit device 12. For example, the device controller 54 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 54 may include a hardware finite state machine (FSM). The device controller 54 may provide other functions, such as serving as a platform for virtual machines that may manage the operation of the integrated circuit device 12.

A network-on-chip (NOC) 56 may connect the various elements of the integrated circuit device 12. The NOC 56 may provide rapid, packetized communication to and from the programmable logic circuitry 40 and other blocks, such as a hardened processor system 58, input/output (I/O) blocks 60, a hardened accelerator 62, and local device memory 64. The integrated circuit device 12 may include the hardened processor system 58 when the integrated circuit device 12 takes the form of a system-on-chip (SOC). The hardened processor system 58 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The I/O blocks 60 may enable communication using any suitable communication protocol(s) with other devices outside of the integrated circuit device 12, such as a separate memory device. The hardened accelerator 62 may include any hardened application-specific integrated circuitry (ASIC) logic to perform a desired acceleration function. For example, the hardened accelerator 62 may include hardened circuitry to perform cryptographic or media encoding or decoding. The memory 64 may provide local device memory (e.g., cache) that may be readily accessible by the programmable logic circuitry 40.

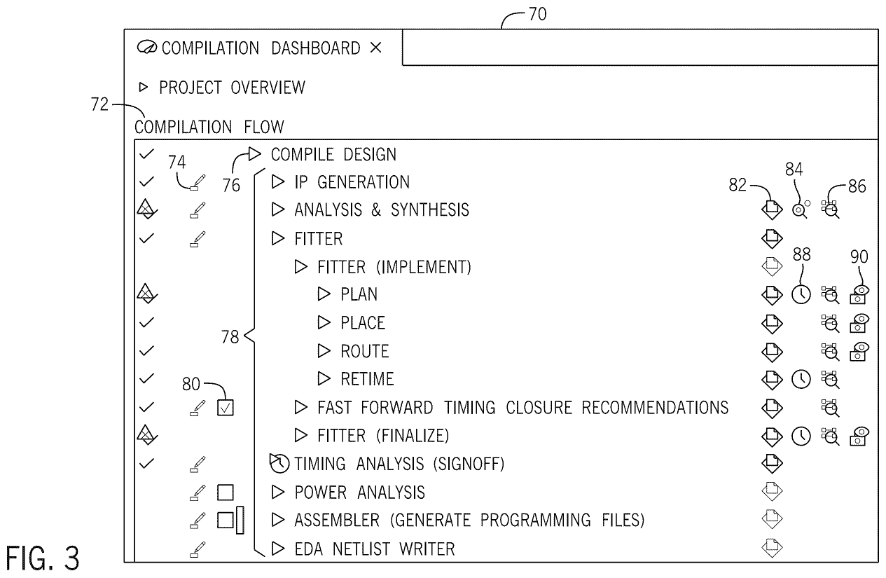

Keeping this in mind, FIG. 3 is a perspective illustration of a compilation dashboard 70 of the design software 18 associated with the integrated circuit 12 of FIG. 1. The compilation dashboard 70 may provide immediate access to settings, controls, and reporting for each stage of a compilation flow 72. In some embodiments, the compilation dashboard 70 may appear by default when the designer (e.g., user) opens a project, or the designer (e.g., user) may click on “compilation dashboard” in a tasks window to re-open the compilation dashboard 70.

In the illustrated embodiment, the designer (e.g., user) may click on a settings icon 74 (e.g., a pencil icon) to edit setting for a respective stage of the compilation flow 72. In addition, the designer (e.g., user) may click on a play icon 76 (e.g., a right-pointing triangle) associated with a compiler stage or a module to run one or more compiler stages. For example, a full compilation may include one or more modules 78. In some embodiments, the designer (e.g., user) may select one or more optional modules to be included (e.g., optional module 80). The designer (e.g., user) may click the play icon 76 associated with the compiler stage to resume an interrupted compilation flow provided no compilation settings have changed from an initial start of the compilation flow. Furthermore, the designer (e.g., user) may click a report icon 82, a register-transfer level (RTL) viewer icon 84, a technology map viewer icon 86, a timing analyzer icon 88, or a snapshot viewer icon 90 for analysis of the compiler stage results.

In some embodiments, as the compiler 20 progresses through the compilation flow 72, the compilation dashboard 70 may update a status of each module and enable icons that may be selected by the designer (e.g., user) for reports and analysis. The compilation dashboard 70 may also update if the designer (e.g., user) runs the compilation flow 72 from a command line with an update command (e.g., quartus_sh--flow).

In addition, report files may be generated to provide feedback, analysis, and results from the compilation flow 72. In some embodiments, the report files may be generated by a tool associated with design software (e.g., Quartus® Design Suite® by Altera Corporation). For example, the report file may be in a design software (e.g., Quartus®) report file format (e.g., <project_name>.<type>.<stage>.rpt).

Some examples of the design software (e.g., Quartus®) report file format include LU240PEEng.drc.partitioned.rpt, LU240PEEng.dre.synthesized.rpt, LU240PEEng.fit.place.rpt, LU240PEEng.fit.plan.rpt, LU240PEEng.fit.route.rpt, LU240PEEng.fit.retime.rpt, LU240PEEng.fit.finalize.rpt, LU240PEEng.fit.drc.finalize.rpt, LU240PEEng.fit.rpt, LU240PEEng.tq.drc.signoffrpt, LU240PEEng.sta.rpt, LU240PEEng.tlg.rpt, LU240PEEng.syn.ae.rpt, LU240PEEng.syn.rpt, and LU240PEEng.flow.rpt.

In some embodiments, output report files may be generated by design software (e.g., Quartus® Design Suite® by Altera Corporation) when compiling the design. For example, a report file (e.g., .rpt) may include a general output report from compilation (e.g., synthesis, fitting, timing). A design assistant report (e.g., .drc.*.rpt) may include results from a design assistant (e.g., rule violations, recommendations). A timing analysis report (e.g., .sta.rpt) may include detailed static timing analysis (e.g., timing paths, slack, violations). A fitter report (e.g., .fit.*.rpt) may include results from a fitter (e.g., resource usage, placement, routing). A synthesis report (e.g., .syn.*.rpt) may include synthesis results (e.g., logic utilization, warnings). A flow report (e.g., .flow.rpt) may include a summary of the compilation flow 72 (e.g., errors, warnings, statistics). A summary file (e.g., .summary) may include a summary of the compilation (e.g., high-level results, stats).

Furthermore, input files may be used to define the design, constraints, and configuration. In some embodiments, the input files may be provided by the designer (e.g., user). For example, the input files may include a settings file, a project file, a platform designer system file, synopsis design constraints, an IP variation file, a Verilog hardware description language (HDL) file, a systemVerilog file, a very high speed integrated circuit (VHSIC) hardware description language (VHDL) file, a tool command language (Tcl) script file, and so on.

The settings file (e.g., .qsf) may store project settings (e.g., device, pin assignments, constraints) that may be used for project configuration. The project file (e.g., .qpf) may include a main project file referencing all project files and may be used to open and/or manage a project. The platform designer system file (e.g., .qsys) may describe a platform designer (Qsys) system (e.g., IP blocks, connections, parameters) and may be used for system integration and IP generation. The Synopsys design constraints (e.g., .sdc) may contain timing constraints for static timing analysis, which may be used for timing closure. The IP variation file (e.g., .ip) may store a configuration and/or parameters for a specific IP core instance and may be used for IP generation. The Verilog HDL file (e.g., .v) may include Verilog source code for hardware design and may be used for synthesis and simulation. The systemVerilog file (e.g., .sv) may include systemVerilog source code for the design and/or verification and may be used for synthesis and simulation. The VHDL file (e.g., .vhd) may include VHDL source code for hardware design and may be used for synthesis and simulation. The Tcl script file (e.g., tcl) may include scripting for automation (e.g., project setup, compilation, IP generation).

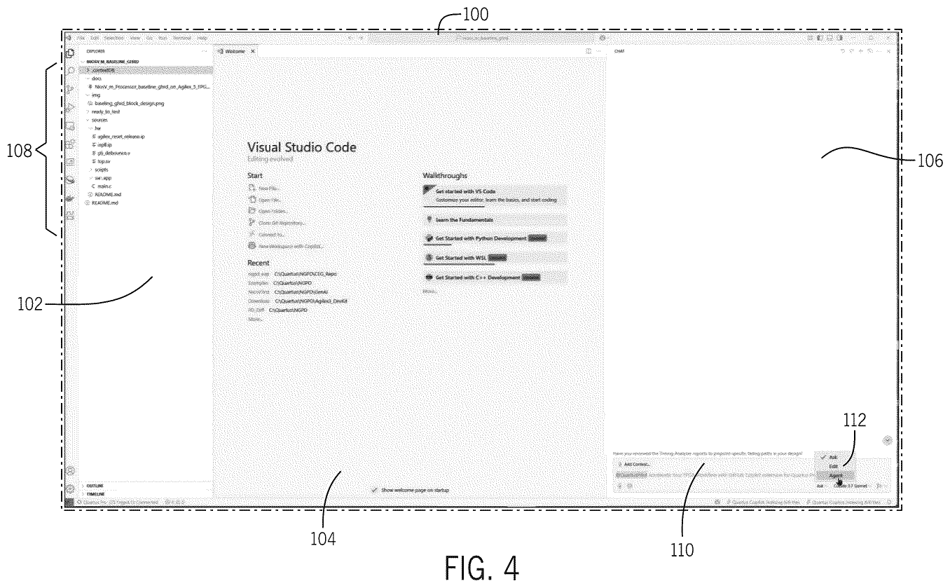

FIG. 4 is a perspective illustration of a graphical user interface (GUI) 100 generated by a design assistant used to design the integrated circuit 12 of FIG. 1. The GUI 100 may include a design region 102, a code region 104, and an assistant region 106. In some embodiments, design files 108 associated with the design of the user may be located in the design region 102. For example, the design files 108 may include Synopsys design constraints (SDC) files, including timing constraints, IPs in the design, the output report files from compiling the design, reports, and so on. Furthermore, respective code based on a selected file of the design files 108 may display in the code region 104. In addition, the designer (e.g., user) may interact with the design assistant 30 in the assistant region 106. For example, the designer (e.g., user) may input text in an input box 110. In some embodiments, the designer (e.g., user) may ask a question pertaining to the design associated with the design files 108.

In some embodiments, the GUI 100 may include a user menu 112. For example, the designer (e.g., user) may select an option from the user menu 112 to tailor the design assistant 30 to focus on a specific task. For example, the user menu 112 may include an ask option, an edit option, and an agent option. The ask option may allow the designer (e.g., user) to ask the design assistant 30 a question regarding the design. Furthermore, the edit option may focus on implementing a change to respective code of the design. Additionally, the agent option may utilize one or more agents to perform a specific task.

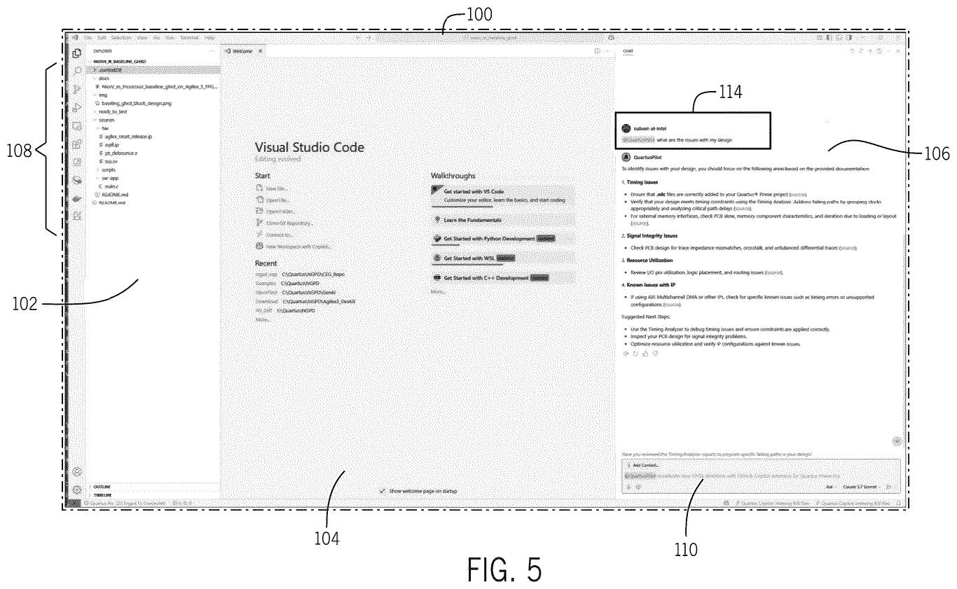

FIG. 5 is a perspective illustration of the GUI 100 of FIG. 4 including an example of a user prompt 114 regarding issues with the design. In the illustrated embodiment, the ask option of the user menu 112 is selected. The user prompt 114 regarding issues with the design and a corresponding response to the user prompt 114 regarding issues with the design may be displayed in the assistant region 106. In this example, the designer (e.g., user) entered “what are the issues with my design.” The design assistant 30 may analyze the user prompt 114 regarding issues with the design and respond accordingly. For example, the design assistant 30 suggested to the designer (e.g., user), “To identify issues with your design, you should focus on the following areas based on the provided documentation.” The design assistant 30 further expanded on timing issues, signal integrity issues, resource utilization, and known issues with IP. Furthermore, the design assistant 30 suggested next steps for the designer (e.g., user).

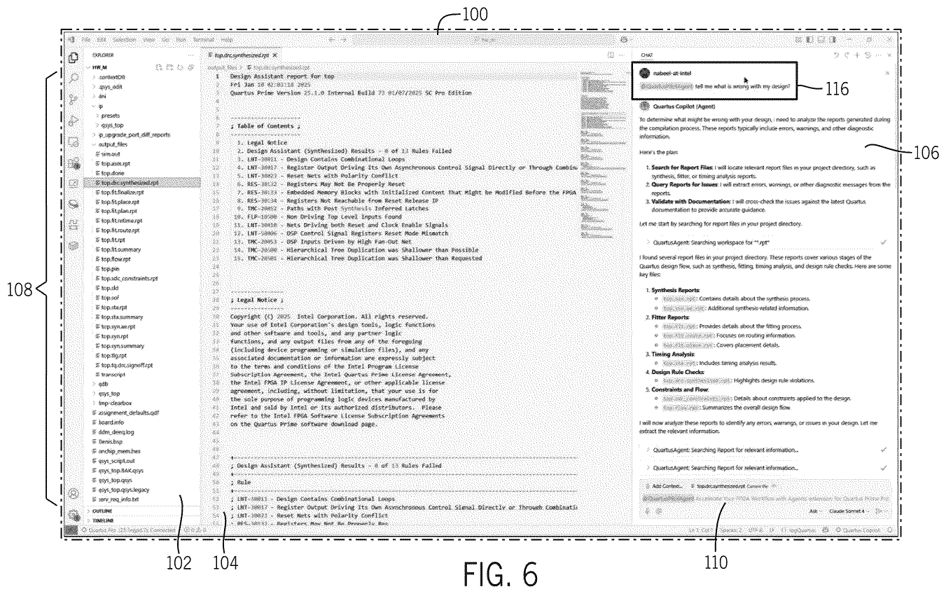

FIG. 6 is a perspective illustration of the GUI 100 of FIG. 4 including an example of another user prompt 116 regarding issues with the design. In the illustrated embodiment, the ask option of the user menu 112 is selected. The user prompt 116 regarding issues with the design and another corresponding response to the user prompt 116 regarding issues with the design may be displayed in the assistant region 106. In this example, the designer (e.g., user) entered “tell me what is wrong with my design?”. The design assistant 30 may analyze the user prompt 116 regarding issues with the design and respond accordingly. For example, the design assistant 30 suggested to the designer (e.g., user), “To determine what might be wrong with your design, I need to analyze the reports generated during the compilation process.” The design assistant 30 may locate relevant files and analyze relevant reports.

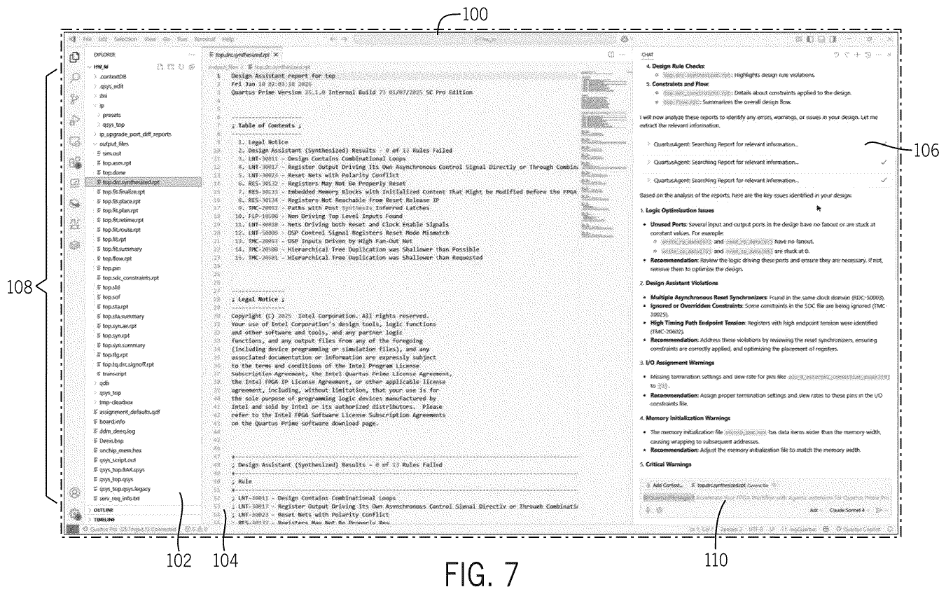

FIG. 7 is a perspective illustration of the GUI 100 of FIG. 4 including an analysis of the issues with the design. In the illustrated embodiment, a continuation of the other corresponding response to the user prompt 116 regarding issues with the design from FIG. 6 is displayed in the assistant region 106. After analyzing the relevant reports, the design assistant 30 may identify key issues with the design.

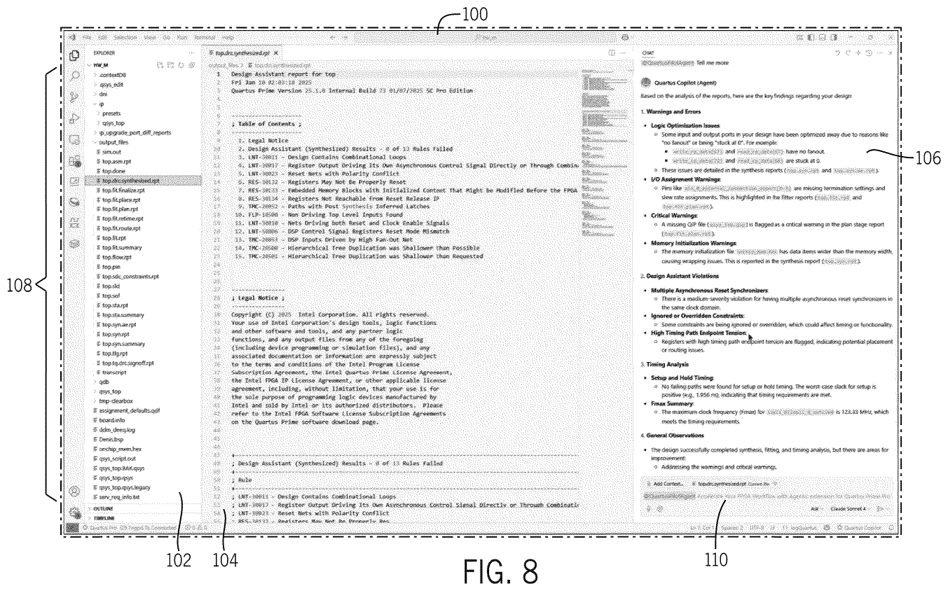

FIG. 8 is a perspective illustration of the GUI 100 of FIG. 4 including an example of a follow up user prompt regarding issues with the design. After receiving a response from the design assistant 30, the designer (e.g., user) may input “[t]ell me more.” In the illustrated embodiment, the design assistant 30 expands on the analysis of the relevant reports and may identify key findings regarding the design.

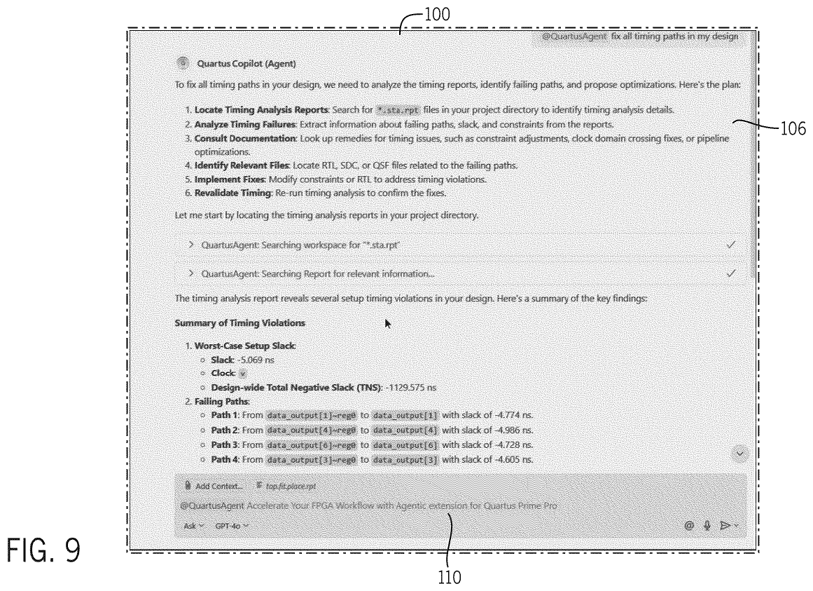

FIG. 9 is a perspective illustration of the GUI 100 of FIG. 4 including an example of a user prompt regarding timing paths in the design. In the illustrated embodiment, the ask option of the user menu 112 is selected. The user prompt regarding timing paths in the design and a corresponding response to the user prompt regarding timing paths in the design may be displayed in the assistant region 106. In this example, the designer (e.g., user) entered “fix all timing paths in my design.” The design assistant 30 may analyze the user prompt regarding timing paths in the design and respond accordingly. For example, the design assistant 30 responded to the designer (e.g., user), “To fix all timing paths in your design, we need to analyze the timing reports, identify failing paths, and propose optimizations.”

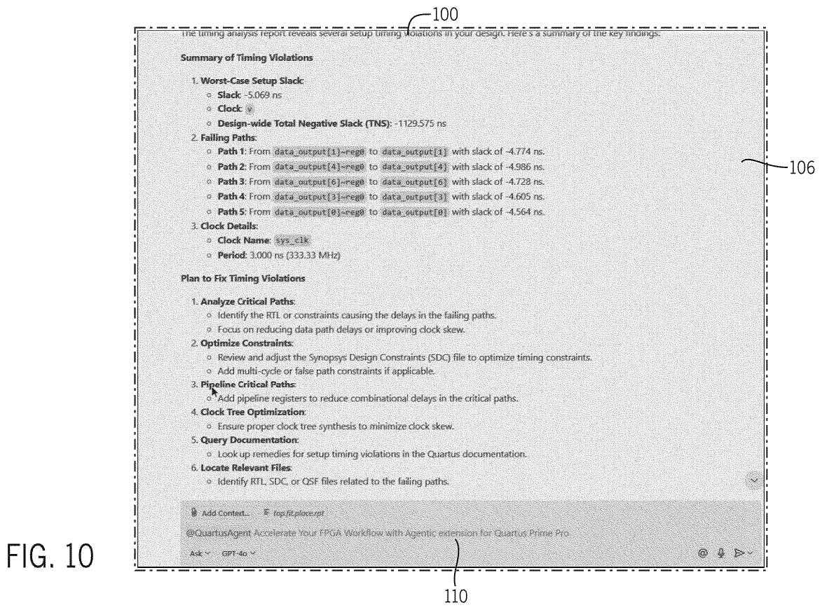

FIG. 10 is a perspective illustration of the GUI 100 of FIG. 4 including an analysis of the timing paths in the design. In the illustrated embodiment, a continuation of the corresponding response to the user prompt regarding timing paths in the design from FIG. 9 is displayed in the assistant region 106. The design assistant 30 may expand on a summary of timing violations and a plan to fix timing violations.

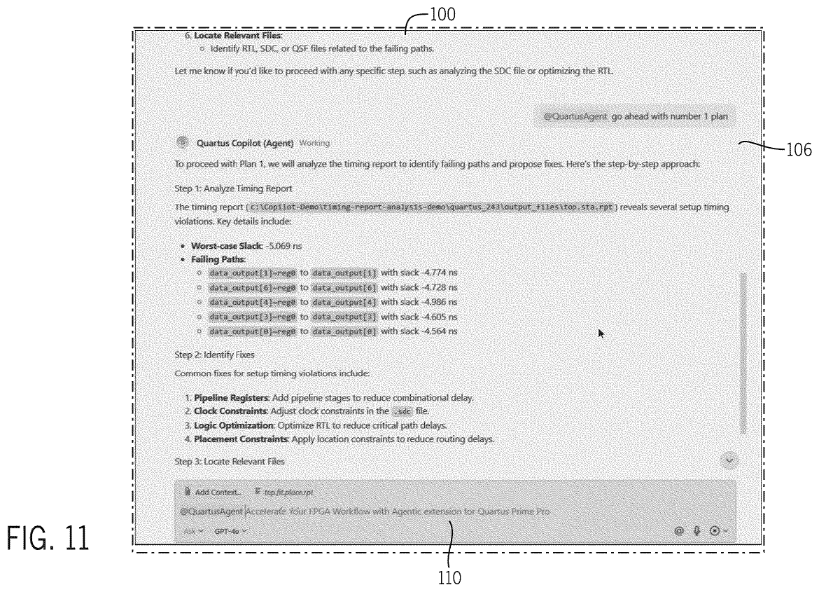

FIG. 11 is a perspective illustration of the GUI 100 of FIG. 4 including an explanation of implementation of a suggestion regarding the timing paths in the design. In the illustrated embodiment, the ask option of the user menu 112 is selected. In the illustrated embodiment, the designer (e.g., user) entered “go ahead with number 1 plan.” The design assistant 30 may proceed based on an input from the designer (e.g., user). For example, the design assistant 30 responded to the designer (e.g., user), “To proceed with Plan 1, we will analyze the timing report to identify failing paths and propose fixes.” The design assistant 30 may further expand on a step-by-step approach to explain any actions taken to the designer (e.g., user).

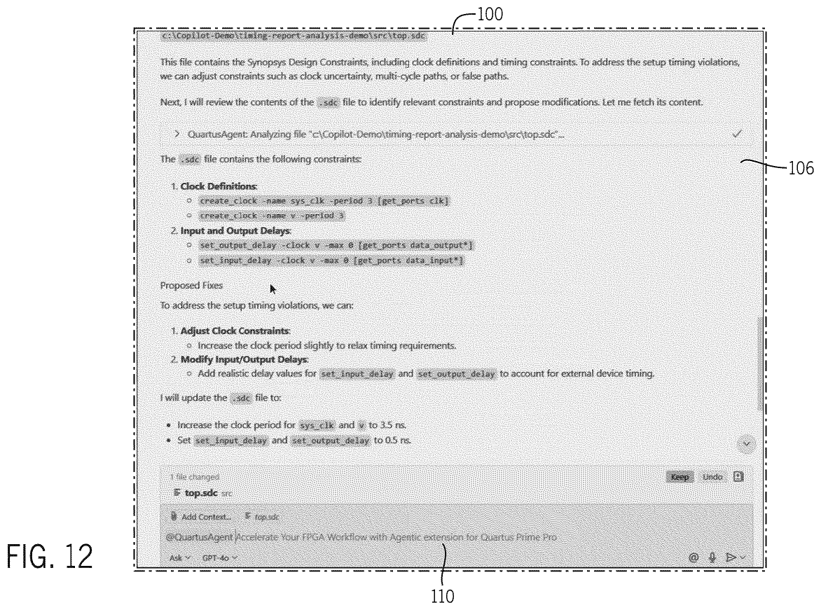

FIG. 12 is a perspective illustration of the GUI 100 of FIG. 4 including another explanation of the implementation of the suggestion regarding the timing paths in the design. As illustrated, the design assistant 30 may continue to expand on the step-by-step approach.

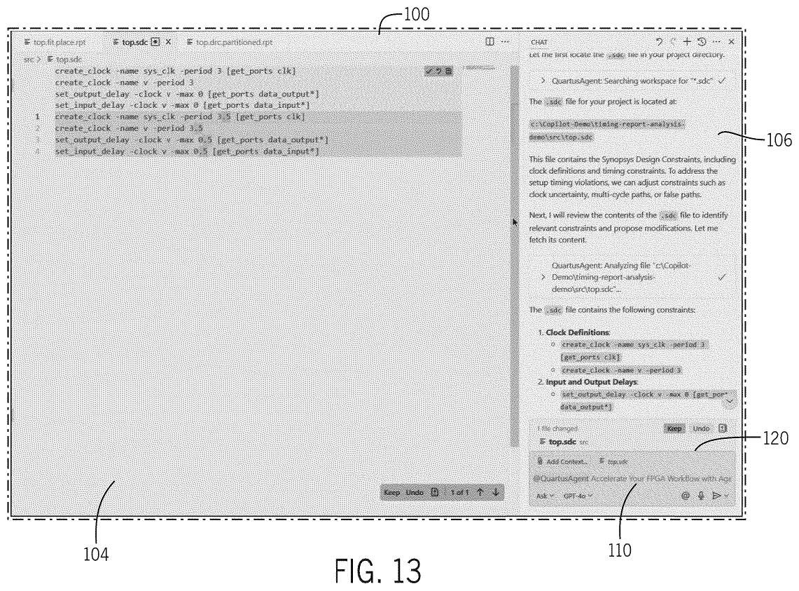

FIG. 13 is a perspective illustration of the GUI 100 of FIG. 4 including the implementation of the suggestion regarding the timing paths in the design described in FIGS. 11 and 12. As illustrated, the design assistant 30 may highlight one or more areas of code. For example, the one or more areas of codes may be highlighted in red. In addition, the design assistant 30 may highlight any suggested changes to be made to the one or more areas of code. For example, the suggested changes may be highlighted in green. This may allow the designer (e.g., user) to easily view any suggested changes to the design. In the illustrated embodiment, the designer (e.g., user) may keep or undo the suggested change via a selection in a selection menu 120. In some embodiments, the design assistant 30 may wait for an indication from the designer (e.g., user) before implementing the suggested changes. The selection menu 120 may enable the designer (e.g., user) additional control and input in conjunction with the design assistant 30.

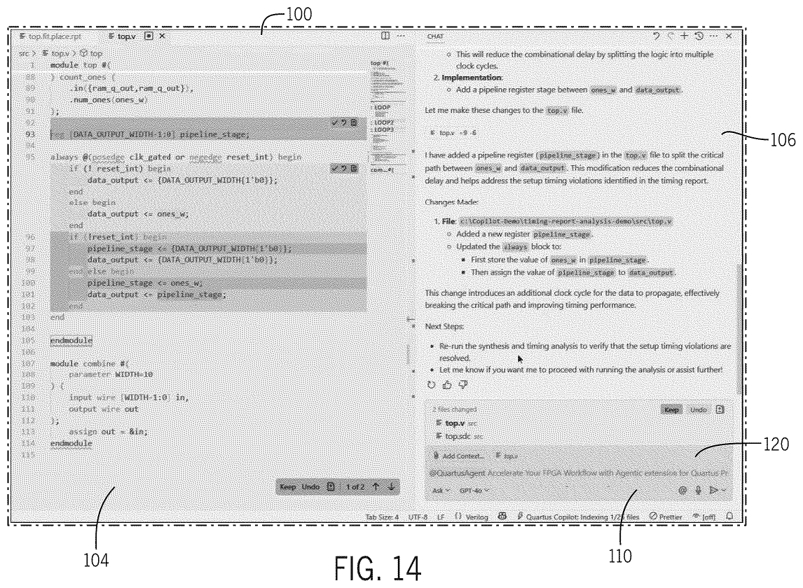

FIG. 14 is a perspective illustration of the GUI 100 of FIG. 4 including implementation of adding pipeline in the design. Similar to FIG. 13, the design assistant 30 may highlight one or more areas of code. For example, the one or more areas of codes may be highlighted in red. In addition, the design assistant 30 may highlight any suggested changes to be made to the one or more areas of code. For example, the suggested changes may be highlighted in green. This may allow the designer (e.g., user) to easily view any suggested changes to the design. In the illustrated embodiment, the designer (e.g., user) may keep or undo the suggested change via the selection in the selection menu 120. In some embodiments, the design assistant 30 may wait for an indication from the designer (e.g., user) before implementing the suggested changes. The selection menu 120 may enable the designer (e.g., user) to have additional control and input in conjunction with the design assistant 30.

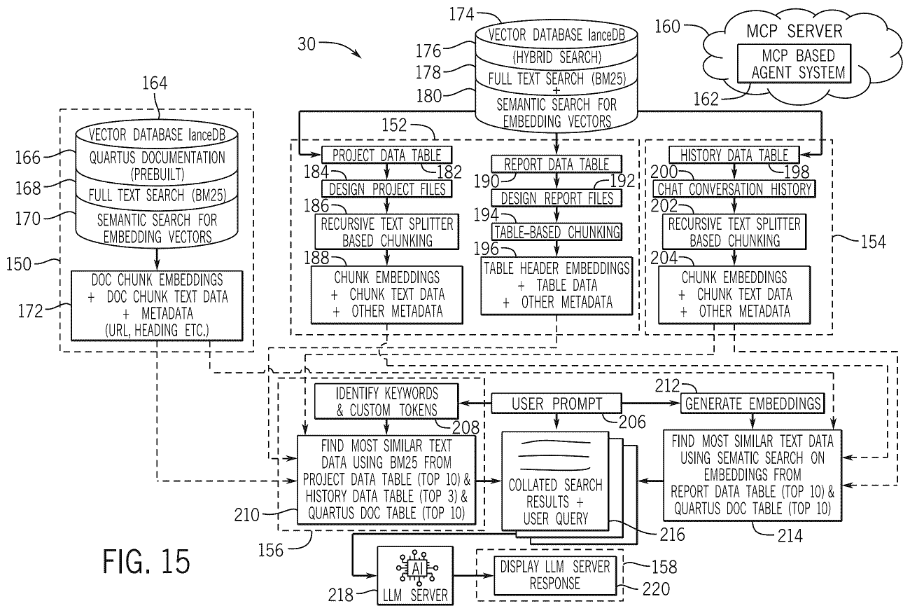

FIG. 15 is a block diagram of an example architecture of the design assistant 30 used to design the integrated circuit 12 of FIG. 1. The design assistant 30 may include a context-aware retrieval system 150, a recursive document splitting and chunking system 152, a design history integration system 154, a dynamic scoping system 156, and a cross-referencing system 158. In some embodiments, the design assistant 30 may communicate with a model context protocol (MCP) server 160 which may include an MCP based agent system 162.

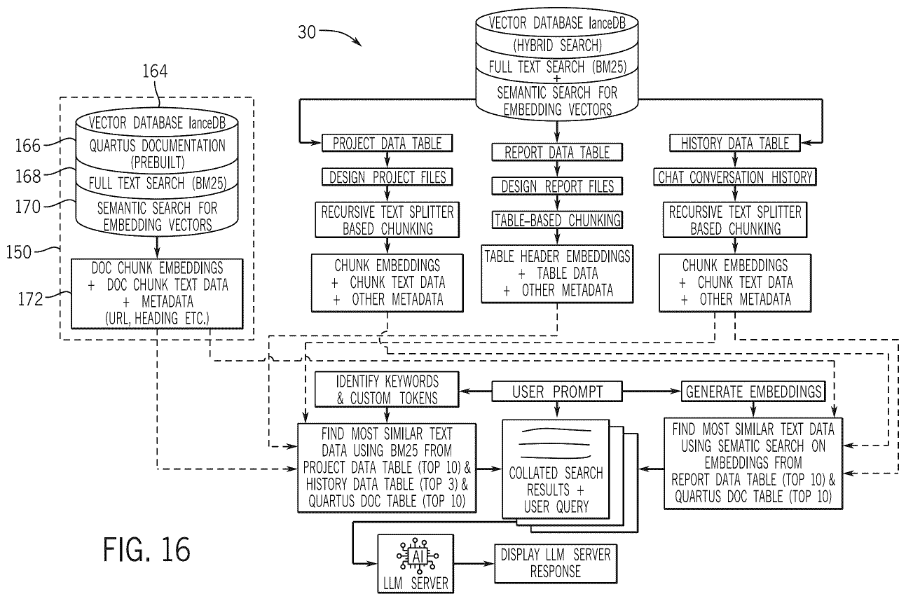

The context-aware retrieval system 150 may be used for FPGA design implementation and closure processes. In some embodiments, the context-aware retrieval system 150 may include a vector database 164. For example, the vector database 164 (e.g., LanceDB) may store design software (e.g., Quartus®) documentation 166 (e.g., prebuilt), a full text search 168 (e.g., using Best Match 25 (BM25)), and a semantic search 170 for embedding vectors. The vector database 164 may be communicatively coupled to a document chunking process 172. The document chunking process 172 may create document chunk embeddings, document chunk text data, and metadata (e.g., URL, heading). The context-aware retrieval system 150 may be further described below with reference to FIGS. 16-28.

In some embodiments, the design assistant 30 may include a vector database 174 (e.g., LanceDB). The vector database 174 may include a hybrid search 176, a full text search 178 (e.g., using BM25), and a semantic search 180 for embedding vectors. In certain embodiments, the recursive document splitting and chunking system 152 and the design history integration system 154 may be communicatively coupled to the vector database 174.

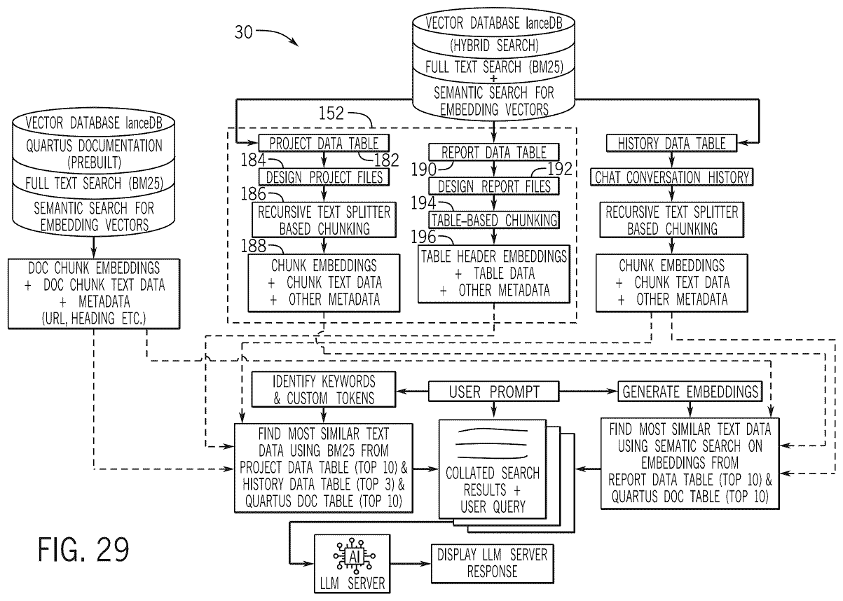

The recursive document splitting and chunking system 152 may be used for FPGA documentation and tool reports. In some embodiments, the recursive document splitting and chunking system 152 may include a project data table 182, design project files 184, recursive text splitter based chunking 186, and a chunking process 188. In some embodiments, the project data table 182, the design project files 184, the recursive text splitter based chunking 186, and the chunking process 188 may be communicatively coupled to each other. The chunking process 188 may create chunk embeddings, chunk text data, and other metadata. Additionally or alternatively, the recursive document splitting and chunking system 152 may include a report data table 190, design report files 192, table-based chunking 194, and a table process 196. In some embodiments, the report data table 190, the design report files 192, the table-based chunking 194, and the table process 196 may be communicatively coupled to each other. The table process 196 may create table header embeddings, table data, and other metadata. The recursive document splitting and chunking system 152 may be further described below with reference to FIGS. 29-38.

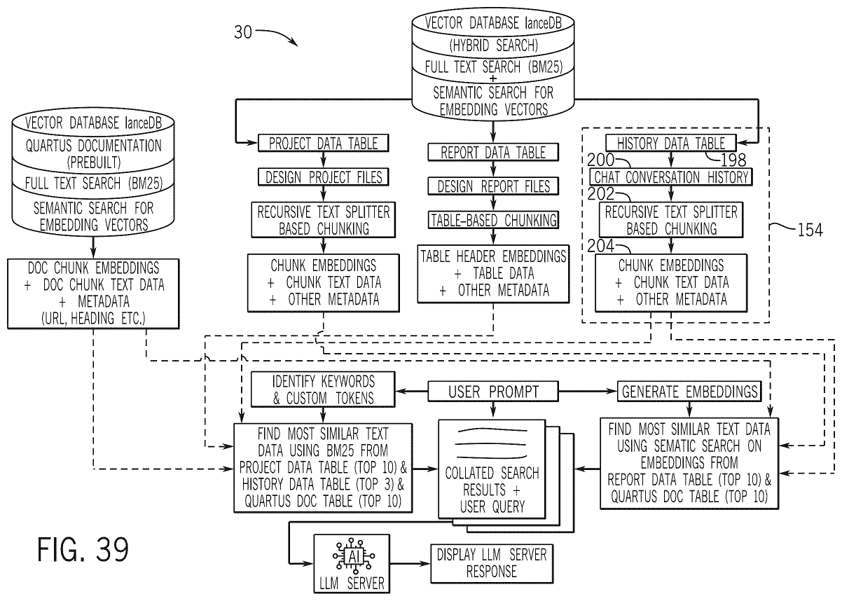

The design history integration system 154 may be used for iterative development. In some embodiments, the design history integration system 154 may include a history data table 198, chat conversation history 200, recursive text splitter based chunking 202, and a chunking process 204. In some embodiments, the history data table 198, the chat conversation history 200, the recursive text splitter based chunking 202, and the chunking process 204 may be communicatively coupled to each other. The chunking process 204 may create chunk embeddings, chunk text data, and other metadata. The design history integration system 154 may be further described below with reference to FIGS. 39-45.

In some embodiments, the design assistant 30 may reference two types of data. For example, a first type of data may be readily available public, which may be stored in a cloud. The first type of data may include general documentation on design software (e.g., Quartus®) or FPGA products. In some embodiments, the first type of data may include the design software (e.g., Quartus®) documentation 166. A second type of data may be specific to a design that a user may be trying to compile in the design software (e.g., Quartus®). The second type of data may include constraints and may be located on a device of the user. In some embodiments, the second type of data is not located anywhere else, for example, in a cloud. The second type of data may include three components, such as project data, report data, and historical data. In some embodiments, the project data may include the project data table 182 and the design project files 184. The report data may include the report data table 190 and the design report files 192. The historical data may include the history data table 198 and the chat conversation history 200.

In some embodiments, the design assistant 30 may receive a user prompt 206. The user prompt 206 may include an input in the input box 110 of the GUI 100 by the designer (e.g., user).

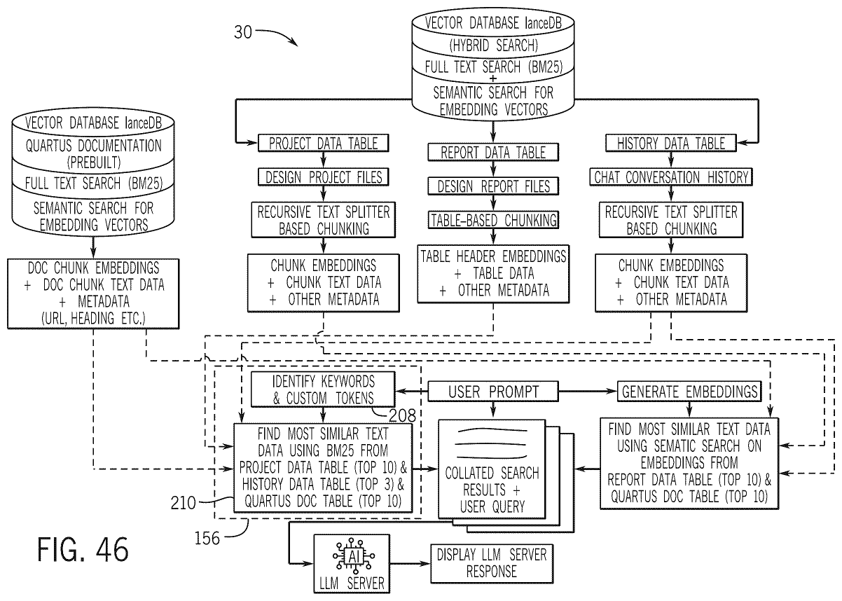

The dynamic scoping system 156 may be used for FPGA design tools and output files. In some embodiments, the dynamic scoping system 156 may include identified keywords and custom tokens 208 and a similar test data process 210. In some embodiments, the identified keywords and custom tokens 208 and the similar test data process 210 may be communicatively coupled to each other. The similar test data process 210 may find most similar text data (e.g., using BM25) from relevant project data tables, relevant history data tables, and relevant design software (e.g., Quartus®) documentation tables. For example, the relevant project data tables may include the ten most relevant project data tables, the relevant history data tables may include the top three most relevant history data tables, and the relevant design software (e.g., Quartus®) documentation tables may include the ten most relevant design software (e.g., Quartus®) documentation tables. In some embodiments, the dynamic scoping system 156 may be communicatively coupled to the context-aware retrieval system 150, the recursive document splitting and chunking system 152, the design history integration system 154, and the user prompt 206. The dynamic scoping system 156 may be further described below with reference to FIGS. 46-52.

In some embodiments, the design assistant 30 may generate embeddings 212. The embeddings 212 may be communicatively coupled to the context-aware retrieval system 150, the recursive document splitting and chunking system 152, the design history integration system 154, and the user prompt 206. Additionally or alternatively, the embeddings 212 may be communicatively coupled to a similar test data process 214 which may be similar to the similar test data process 210. The similar test data process 214 may find most similar text data (e.g., using semantic search on embeddings) from relevant report data tables and relevant design software (e.g., Quartus®) documentation tables. For example, the relevant report data tables may include the ten most relevant project data tables and the relevant design software (e.g., Quartus®) documentation tables may include the ten most relevant design software (e.g., Quartus®) documentation tables.

In certain embodiments, the design assistant 30 provide collated search results 216 which may include a user query. In some embodiments, the collated search results 216 may be communicatively coupled to the dynamic scoping system 156, the user prompt 206, and the similar test data process 214. Additionally or alternatively, the collated search results 216 may be communicatively coupled to a large language model (LLM) server 218. In some embodiments, the LLM server 218 may be communicatively coupled to the cross-referencing system 158.

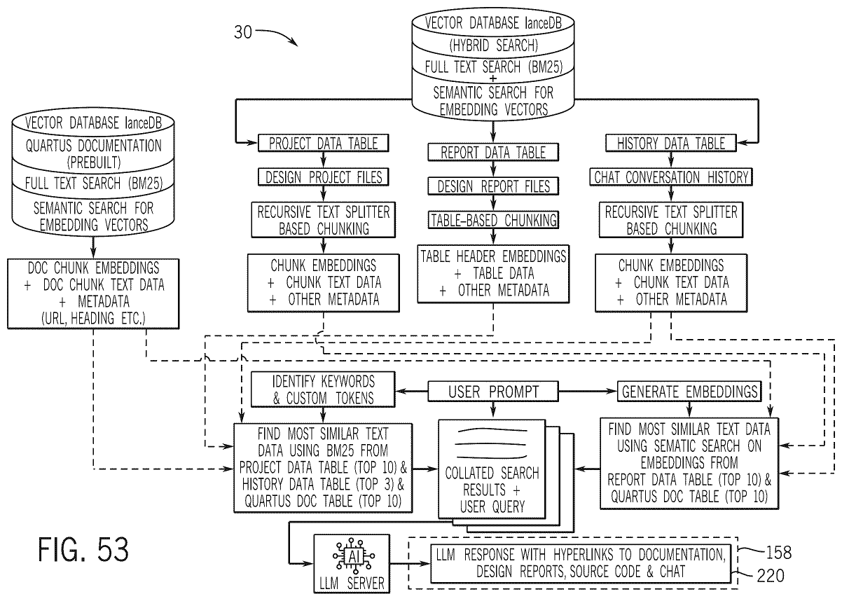

The cross-referencing system 158 may be used for FPGA documentation, design reports, source code, and chat history. In some embodiments, the cross-referencing system 158 may include a display 220 to display a response associated with the LLM server 218. The cross-referencing system 158 may be further described below with reference to FIGS. 53-61.

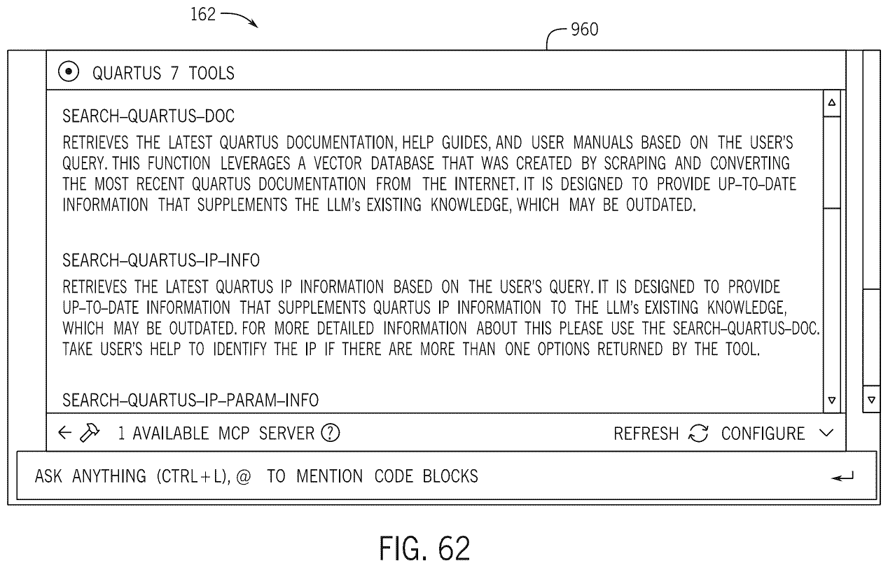

The MCP based agent system 162 may be used for FPGA design tools. In certain embodiments, the MCP based agent system 162 may be communicatively coupled to the design assistant 30. The MCP based agent system 162 may be further described below with reference to FIGS. 62-77.

FIG. 16 is a block diagram of the context-aware retrieval system 150 of the design assistant 30 of FIG. 15. In some embodiments, the context-aware retrieval system 150 may be designed explicitly for an FPGA workflow. For example, the context-aware retrieval system 150 may index, embed, and retrieve FPGA-specific data types while maintaining relationships between different design stages. The context-aware retrieval system 150 may use specialized embedding techniques to link related information (e.g., timing analysis to HDL code). Additionally or alternatively, the context-aware retrieval system 150 may rank results based on relevance to current design context. In some embodiments, the context-aware retrieval system 150 may update before receiving a query from the design (e.g., user).

The context-aware retrieval system 150 may accelerate FPGA design closure by enabling the designer (e.g., user) to find relevant information across all design stages through natural language queries more efficiently than traditional techniques. The context-aware retrieval system 150 may reduce design iteration time by automatically surfacing related information from synthesis, timing, and other reports that may be relevant to a current design challenge.

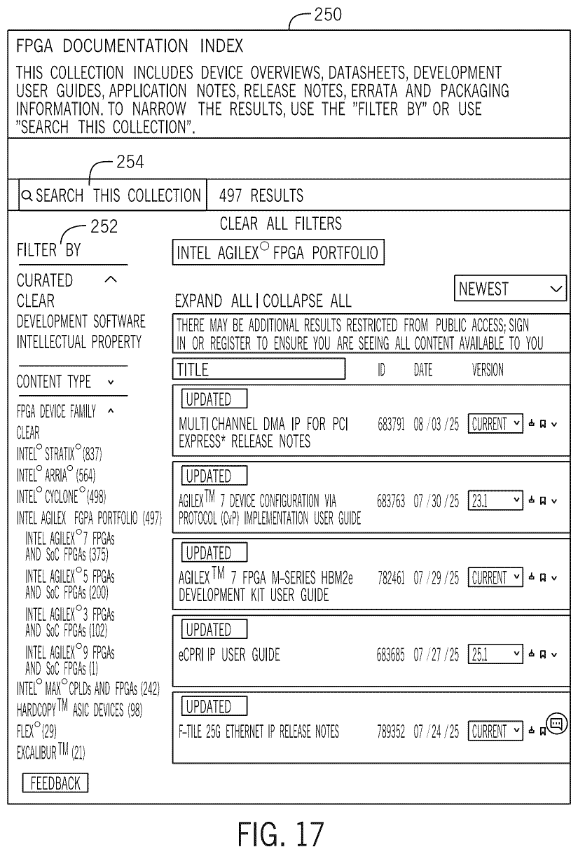

FIG. 17 is an illustration of an example of a FPGA documentation index 250 associated with the design assistant 30 of FIG. 15. In some embodiments, the FPGA documentation index 250 may include device overviews, datasheets, development user guides, application notes, release notes, errata and packaging information, and the like. To narrow results, the designer (e.g., user) may use a filter feature 252 (e.g., filter by) and/or use a search feature 254 (e.g., search this collection).

FIG. 18 is an illustration of an example of violation internal design software (e.g., Quartus®) knowledge 260 with the design assistant 30 of FIG. 15. For example, the violation internal design software (e.g., Quartus®) knowledge 260 may contain information regarding design assistant 30 violation data. The violation internal design software (e.g., Quartus®) knowledge 260 may help resolve issues regarding a design assistant/rule violation (DRC). For example, an issue such as how to fix a given DRC.

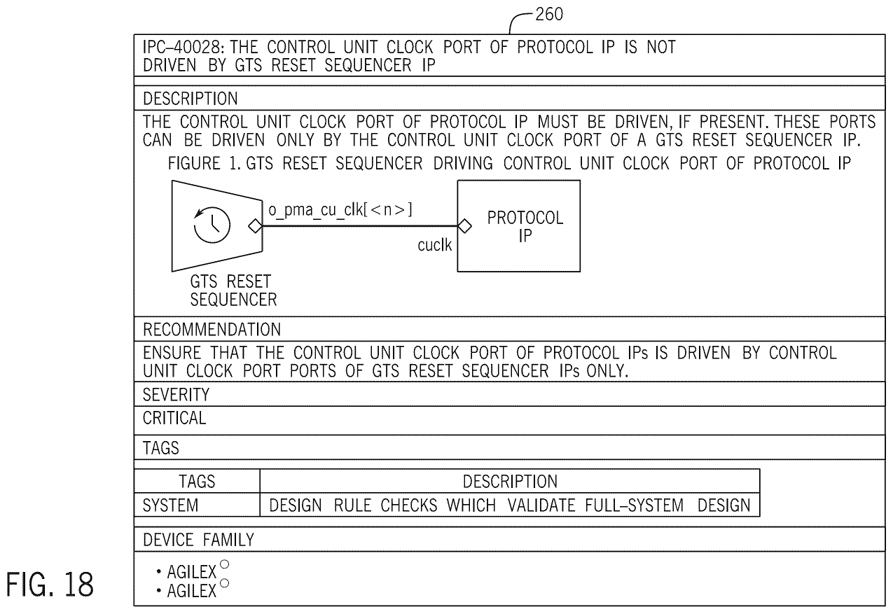

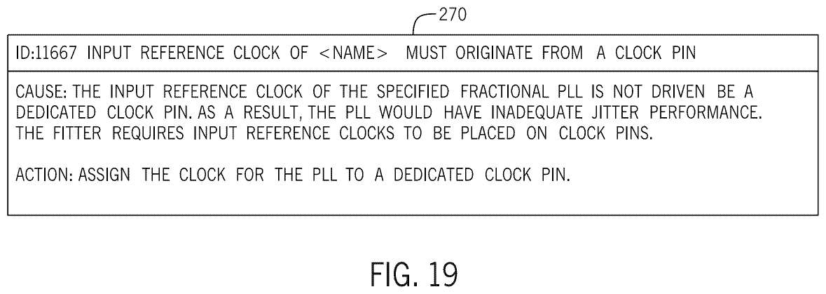

FIG. 19 is an illustration of an example of message internal design software (e.g., Quartus®) knowledge 270 associated with the design assistant 30 of FIG. 15. For example, the message internal design software (e.g., Quartus®) knowledge 270 may contain information regarding a design software (e.g., Quartus®) message database. The design software (e.g., Quartus®) message database may include information regarding a description associated with an Error ID and/or a warning ID. The message internal design software (e.g., Quartus®) knowledge 270 may help resolve issues regarding an error and/or warning. For example, an issue such as what to fix regarding the error and/or warning generated during a design software (e.g., Quartus®) design flow.

FIG. 20 is an illustration of example designs 280 associated with the design assistant 30 of FIG. 15. For example, the example designs 280 may provide a comprehensive list of example designs for Altera's FPGA families. The designer (e.g., user) may filter the example designs 280 by applying search criteria (e.g., via an entry box). Furthermore, the designer (e.g., user) may use a clear feature (e.g., a clear button) to clear previous search criteria.

In some embodiments, the design (e.g., user) may use filter fields to narrow a search. For example, the filter fields may include supported devices (e.g., Agilex 5@, Agilex7®, Stratix 10@, Arria 10@, Cyclone V®), category (e.g., Nios V, PCIe, memory, HPS, networking, TSN, 1588PTP, robotics, video/vision, AI, transceiver), design type (e.g., system example designs, tutorial example designs), development kit target (e.g., search by device name to narrow down the development targets), design software (e.g., Quartus®) version (e.g., via entering “pro” or “std” and a Quartus® version number), description (e.g., via reviewing a description to identify if an example design meets specified needs), and documentation (e.g., a link may take the designer (e.g., user) to an appropriate documentation so the designer (e.g., user) may get started with their design). The system example designs may contain multiple IPs in a broadly applicable design including software and drivers. Furthermore, the tutorial example designs may teach how to use a feature, function or device capability with a simple example.

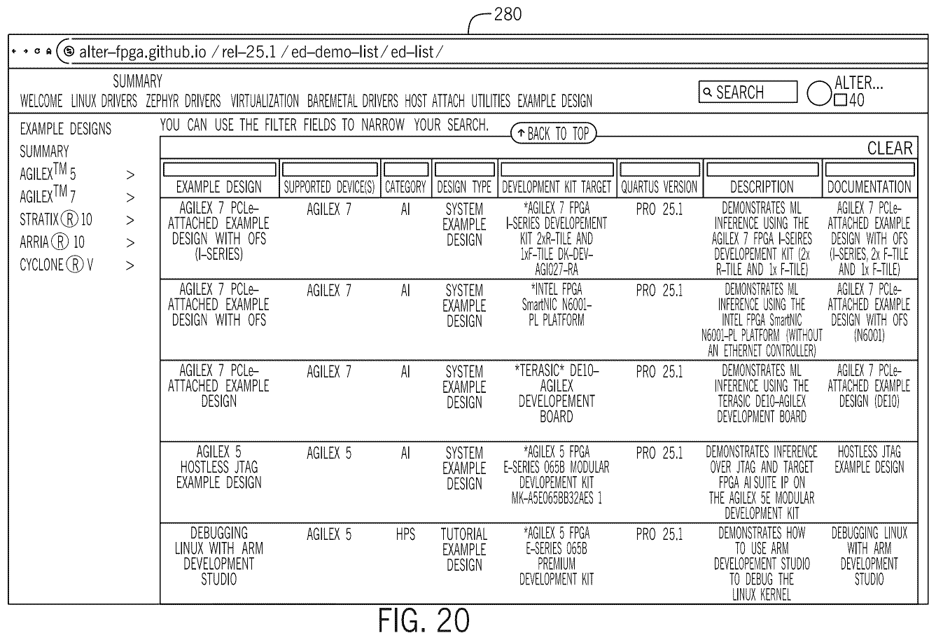

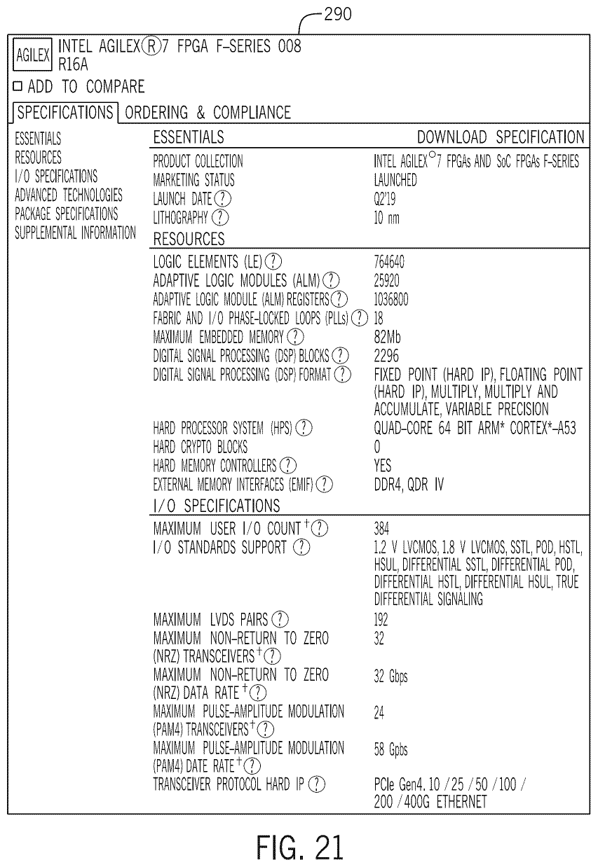

FIG. 21 is an illustration of an example of device documentation 290 associated with the design assistant 30 of FIG. 15. In some embodiments, the device documentation 290 may be stored in the design software (e.g., Quartus®) documentation 166.

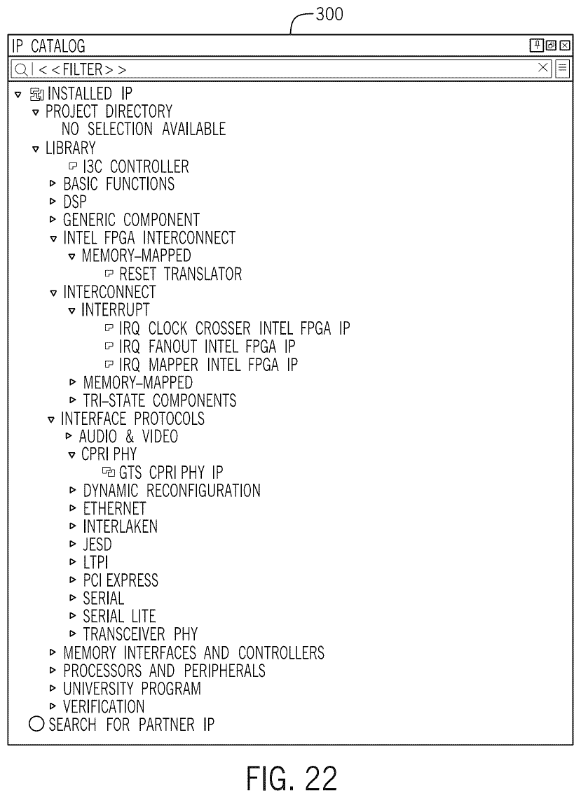

FIG. 22 is an illustration of example of IP catalog data 300 associated with the design assistant 30 of FIG. 15. The IP catalog data 300 may include data related to various IP modules available for the designer (e.g., user) to create a design (e.g., FPGA design). For example, the designer (e.g., user) may instantiate IP modules into the design including Ethernet, Interlaken, PCI Express (PCIe), etc.

In some embodiments, the design assistant 30 may embed documents. Embeddings may be created through a process of converting a numerical representation of data (e.g., text, images, or audio) into a high-dimensional vector (e.g., an array of numbers). The process described above may be called embedding, and a resulting vector (e.g., the high-dimensional vector) may be called an embedding. In some embodiments, the embeddings may be used in a semantic search, recommendation systems, clustering similar items, and the like.

In vector databases (e.g., vector DBs), data (e.g., a sentence or image) may be passed through a model (e.g., a neural network) to generate the embedding. For example, the embedding may capture a semantic meaning of the data. Therefore, similar items may have similar vectors. The vectors may be stored in a vector database. If the designer (e.g., user) is trying to find similar items, the design assistant 30 may generate an embedding for a query of the designer (e.g., user). The design assistant 30 may search for vectors in the vector database that may be close to the query. For example, the design assistant 30 may search using similarity metrics (e.g., cosine similarity or Euclidean distance).

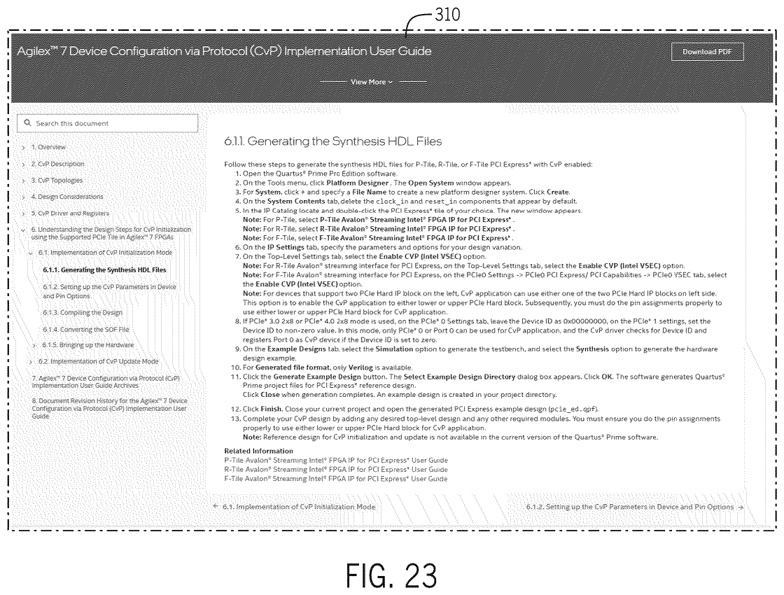

FIG. 23 is an illustration of an example of documentation 310 used in a documentation embedding creation associated with the design assistant 30 of FIG. 15. In some embodiments, documentation 310 may be stored in the design software (e.g., Quartus®) documentation 166. In one specific example shown in FIG. 23, the documentation 310 may include a subsection, “6.1.1. Generating the Synthesis HDL Files.” As illustrated, the subsection may include steps to generate synthesis HDL files.

In some embodiments, the design assistant 30 may follow an embedding creation process. For example, the design assistant 30 may extract data from a subsection (e.g., 6.1.1. Generating the Synthesis HDL Files). A chunk may include a portion of data which may include overlapping data with a preceding chunk, a following chunk, or both. A chunk of data may include an entire subsection of data (e.g., 6.1.1 Generating the Synthesis HDL Files). For example, the chunk of data may belong to a main article (e.g., Main Article: Agilex™ 7 Device Configuration via Protocol (CvP) Implementation User Guide).

The design assistant 30 may generate breadcrumbs to maintain context. For example, the breadcrumbs might reveal a trail leading from the main article (e.g., Main Article: Agilex™ 7 Device Configuration via Protocol (CvP) Implementation User Guide) to a section (e.g., Section 6. Understanding the Design Steps for CvP Initialization using the Supported PCIe Tile in Agilex™ 7 FPGAs) to a subsection (e.g., Sub Section 6.1. Implementation of CvP Initialization Mode) to another subsection (e.g., 6.1.1. Generating the Synthesis HDL Files) that will be used as a chunk of data.

In some embodiments, the design assistant 30 may collect metadata regarding the chunk of data (e.g., the chunk). The metadata may include which main article the chunk belongs to, which subsection the chunk belongs to, breadcrumb for the chunk, main article URL, subsection URL, which device this documentation applicable to (e.g., Agilex 7, Agilex 5), content type (e.g., development software guide, intellectual property (IP) guide, datasheet group), content subtype (e.g., application notes, design example, customer advisories), and the like. The embedding creation process may include creating an embedding for a section and adding respective metadata.

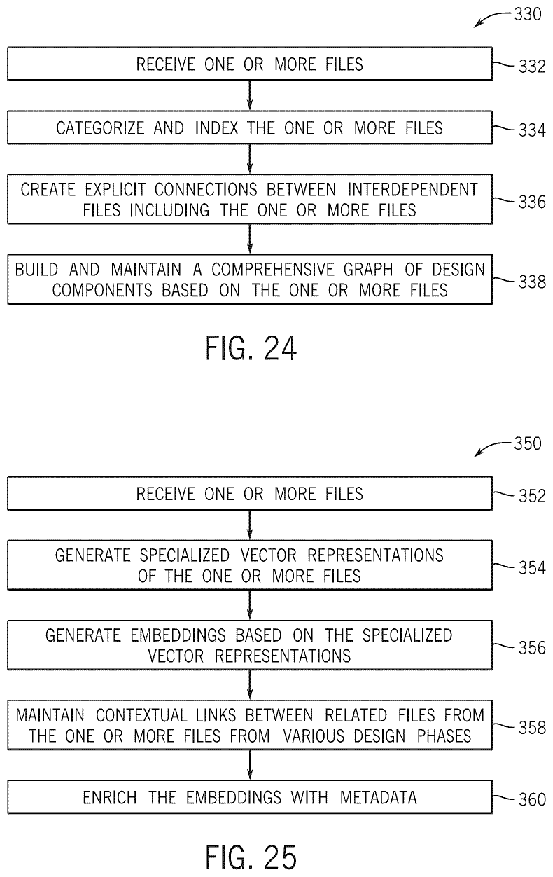

FIG. 24 is a flowchart of an example method 330 for specialized data indexing of the context-aware retrieval system 150 of FIG. 16. For example, the design assistant 30 may receive one or more files (block 332). In some embodiments, the one or more files may be FPGA-specific file types (e.g., HDL code, compiler reports, timing reports). Additionally or alternatively, the one or more filed may be stored on a local device.

The design assistant 30 may categorize and index the one or more files (block 334). In some embodiments, the design assistant 30 may use one or more specialized algorithms to categorize and index diverse design artifacts (e.g., FPGA design artifacts). For example, the one or more specialized algorithms may analyze a unique structure and content of each file type of the one or more files.

The design assistant 30 may create explicit relationships (e.g., connections) between interdependent files including the one or more files (block 336). For example, the design assistant 30 may enable the designer (e.g., user) to trace design decisions across multiple documents and stages. Therefore, the design assistant 30 may maintain relationships between related design files and reports.

The design assistant 30 may build and maintain a comprehensive graph of design components based on the one or more files (block 338). For example, the design assistant 30 may preserve hierarchical relationships and dependencies for more contextually relevant retrieval. Therefore, the design assistant 30 may track design hierarchy and dependencies.

The method 330 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 330 may be performed by separate systems or devices.

FIG. 25 is a flowchart of an example method 350 for context-aware embedding of the context-aware retrieval system 150 of FIG. 16. For example, the design assistant 30 may receive one or more files (block 352). In some embodiments, the one or more files may be FPGA-specific file types (e.g., HDL code, compiler reports, timing reports).

The design assistant 30 may generate specialized vector representations of the one or more files (block 354). In some embodiments, the design assistant 30 may generate the specialized vector representations of the one or more files by encoding domain-specific FPGA terminology and concepts. Encoding domain-specific FPGA terminology and concepts may ensure accurate semantic analysis of technical content.

The design assistant 30 may generate embeddings based on the specialized vector representations (block 356). In some embodiments, the embeddings may capture FPGA-specific technical concepts.

The design assistant 30 may maintain contextual links between related files from the one or more files from various design phases (block 358). Additionally or alternatively, the design assistant 30 may maintain contextual links between related artifacts from various design phases. In some embodiments, the design assistant 30 may enable seamless navigation across a design flow. Therefore, the design assistant 30 may preserve relationships between different design stages.

The design assistant 30 may enrich the embeddings with metadata (block 360). In some embodiments, the metadata may be associated with a design structure and/or performance metrics. For example, the design assistant 30 may enable more precise and relevant search results. Therefore, the design assistant 30 may incorporate design context such as hierarchy, timing paths, resources usage, and the like.

The method 350 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 350 may be performed by separate systems or devices.

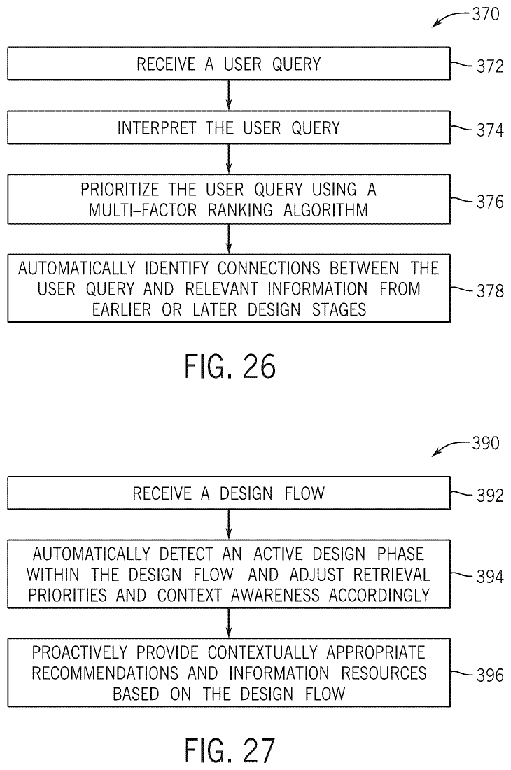

FIG. 26 is a flowchart of an example method 370 for an intelligent retrieval system of the context-aware retrieval system 150 of FIG. 16. For example, the design assistant 30 may receive a user query (block 372).

The design assistant 30 may interpret the user query (block 374). In some embodiments, the design assistant 30 may interpret the user query using one or more specialized NLP models. Additionally or alternatively, the one or more specialized NLP models may be trained on FPGA-specific vocabulary and connects. For example, the design assistant 30 may accurately match intent to relevant design artifacts. Therefore, the design assistant 30 may process natural language queries with an analysis of FPGA terminology.

The design assistant 30 may prioritize the user query using a multi-factor ranking algorithm (block 376). In some embodiments, the multi-factor ranking algorithm may consider current design stage, recently viewed files, active design challenges, and the like. Therefore, the design assistant 30 may rank results based on relevance to current design context.

The design assistant 30 may automatically identify relationships (e.g., connections) between the user query and relevant information from earlier or later design stages (block 378). For example, the design assistant 30 may provide comprehensive context for problem-solving. Therefore, the design assistant 30 may link related information across different design stages.

The method 370 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 370 may be performed by separate systems or devices.

FIG. 27 is a flowchart of an example method 390 for workflow integration of the context-aware retrieval system 150 of FIG. 16. For example, the design assistant 30 may receive a design flow (block 392). In some embodiments, the design flow may be a design software (e.g., Quartus®) design flow. For example, the design assistant 30 may operate as a native component within Microsoft® Visual Studio Code and interoperate with the design software (e.g., Quartus®). Therefore, the design assistant 30 may provide enhanced information retrieval capabilities in an IDE. In some embodiments, the design assistant 30 may seamlessly integrate with an existing design software (e.g., Quartus®) design flow.

The design assistant 30 may automatically detect an active design phase within the design flow and adjust retrieval priorities and context awareness accordingly (block 394). For example, the design assistant 30 may update context based on a current design state.

The design assistant 30 may proactively provide contextually appropriate recommendations and information resources based on the design flow (block 396). For example, the design assistant 30 may provide relevant suggestions based on design progress, and on which stage of the implementation process the design is at, e.g. synthesis, plan, placement, routing, retiming, etc.

The method 390 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 390 may be performed by separate systems or devices.

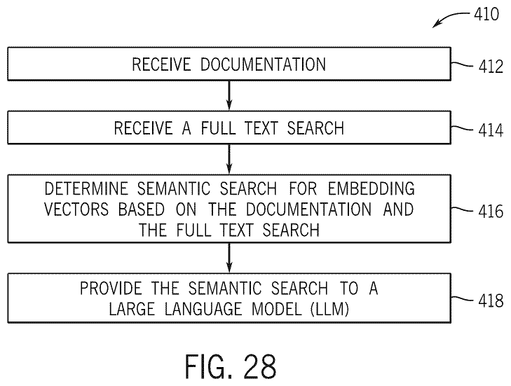

FIG. 28 is a flowchart of an example method 410 for the context-aware retrieval system 150 of FIG. 16. For example, the design assistant 30 may receive documentation (block 412). In some embodiments, the documentation may include the documentation 310. Additionally or alternatively, the design assistant 30 may reference the design software (e.g., Quartus®) documentation 166.

The design assistant 30 may receive a full text search (block 414). In some embodiments, the full text search may be the user query. For example, the full text search may be inputted by the designer (e.g., user) via the input box 110. Additionally or alternatively, the design assistant 30 may reference the full text search 168.

The design assistant 30 may determine semantic search for embedding vectors based on the documentation and the full text search (block 416). Additionally or alternatively, the design assistant 30 may reference the semantic search 170.

The design assistant 30 may provide the semantic search to an LLM (block 418). Additionally or alternatively, the design assistant 30 may reference the LLM server 218.

The method 410 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 410 may be performed by separate systems or devices.

In some embodiments, the context-aware retrieval system 150 may include LLM integration and data security. For example, the context-aware retrieval system 150 may employ advanced retrieval-augmented generation (RAG) techniques to maximize information utility while minimizing an amount of design data used for effective operation. Therefore, the context-aware retrieval system 150 may optimize RAG implementation with minimal design data. In some embodiments, a flexible backend may connect to various LLM providers, which may allow organizations to choose models based on a specific performance, infrastructure, and/or security requirements. Therefore, an LLM-agnostic architecture may support any publicly available language model or private language model. In some embodiments, comprehensive encryption protocols may protect sensitive design information throughout a processing pipeline. Therefore, end-to-end encryption for all design-specific data may be possible. In some embodiments, the context-aware retrieval system 150 may automatically identify and protect confidential design elements before processing. Therefore, the context-aware retrieval system 150 may secure tokenization and sanitization of sensitive information. In some embodiments, design artifacts may be secured using enterprise-grade protection measures during both storage and communication. Therefore, the context-aware retrieval system 150 may protect storage and transmission of design data.

In some embodiments, the design data associated with the design may be stored on a local device. For example, the design data may not reside in a memory of the design assistant 30. Additionally or alternatively, a portion of the design data may be encrypted.

In some embodiments, the context-aware retrieval system 150 may include GUI enhancements. For example, the context-aware retrieval system 150 may incorporate an intuitive natural language query interface. Additionally or alternatively, a user-friendly interface may accept conversational queries about design issues. The user-friendly interface may eliminate complex search syntax or specialized query languages. In some embodiments, as the designer (e.g., user) types, the context-aware retrieval system 150 may provide intelligent query completions and suggestions based on the current design context. Therefore, the context-aware retrieval system 150 may provide real-time query suggestions and refinements. In some embodiments, search results may be displayed with relevant contextual information and visualizations to highlight a significance to the current design challenge. Therefore, the context-aware retrieval system 150 may provide a context-aware result presentation. In some embodiments, the designer (e.g., user) may dynamically refine search results through intuitive filtering options that adapt to a specific result set. Therefore, the context-aware retrieval system 150 may provide interactive result filtering and exploration. In some embodiments, the context-aware retrieval system 150 may offer multiple ways to view and interact with search results. The context-aware retrieval system 150 may accommodate different user preferences and problem-solving approaches. Therefore, the context-aware retrieval system 150 may provide customizable result visualization.

FIG. 29 is a block diagram of the recursive document splitting and chunking system 152 of the design assistant 30 of FIG. 15. In some embodiments, the recursive document splitting and chunking system 152 may be designed explicitly for FPGA documentation and tool reports. For example, the recursive document splitting and chunking system 152 may chunk content while preserving technical context and relationships in the FPGA documentation and tool reports. Additionally or alternatively, the recursive document splitting and chunking system 152 may use FPGA-specific knowledge to identify logical boundaries and maintain hierarchical information structure.

The recursive document splitting and chunking system 152 may significantly improve accuracy of information retrieval in FPGA workflows. For example, the recursive document splitting and chunking system 152 may ensure technical content may be split in a meaningful way. Additionally or alternatively, the recursive document splitting and chunking system 152 may lead to more precise search results and better integration with an LLM for FPGA design assistance.

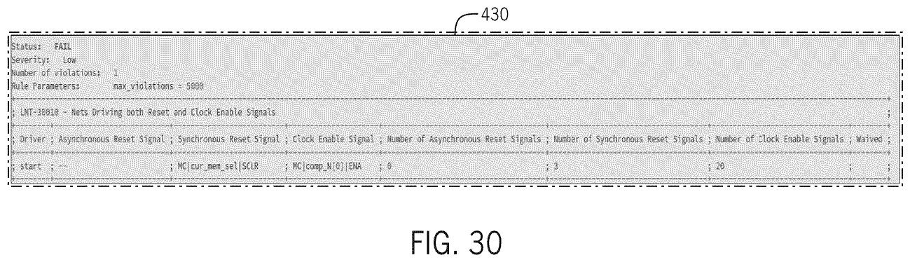

FIG. 30 is an illustration of an example of a report file 430 used in a design data embedding creation associated with the design assistant 30 of FIG. 15. For example, the recursive document splitting and chunking system 152 may extract data from the report file 430 (e.g., the design report files 192). As illustrated, the data from the report file 430 may be in a table format. The recursive document splitting and chunking system 152 may extract the data including headers from the report file 430. Additionally or alternatively, the recursive document splitting and chunking system 152 may collect metadata from the report file 430. The recursive document splitting and chunking system 152 may extract a table header (e.g., FAIL, LNT-30023—Reset Nets with Polarity Conflict).

In some embodiments, the metadata may include a file type (e.g., Verilog, vhdl, dre report file, timing report file), a file location, a table start line, a table end line, a design software (e.g., Quartus®) report type (e.g., DRC, timing, fitter), a table data type (e.g., DRC failures, timing data, module definition, resource summary), a design software (e.g., Quartus®) stage (e.g., analysis and elaboration, synthesis, fitter, plan, place), and the like.

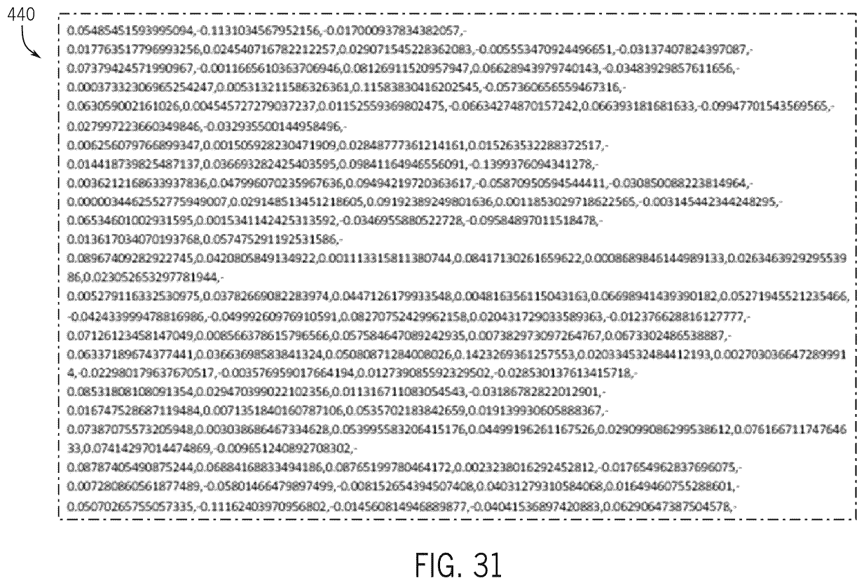

FIG. 31 is an illustration of an example of an embedding generation 440 associated with the design assistant 30 of FIG. 15. For example, the embedding generation 440 may be based on the data from the report file 430 of FIG. 30. The recursive document splitting and chunking system 152 may create a vector database based on the embedding generation 440. Additionally, or alternatively, the recursive document splitting and chunking system 152 may use actual data in text format. The recursive document splitting and chunking system 152 may attach various metadata for better retrieval of the data (e.g., the data from the report file 430).

FIG. 32 is an illustration of an example of a data table 460 associated with the design assistant 30 of FIG. 15. Depending on a size of a file, the file may be split into chunks (e.g., 5, 10, 20). The recursive document splitting and chunking system 152 may keep a portion of data from a previous chunk and a portion of data from a following chunk to make a relationship (e.g., connection) between the chunks. As illustrated, data from the file may be in a tabular format, such as the data table 460. Additionally, or alternatively, the recursive document splitting and chunking system 152, may ensure headers from a table within the file remain in the chunks.

As illustrated, a first chunk of data 462 may include ten data entries (e.g., lines 130 through 139). A second chunk of data 464 may include ten data entries (e.g., lines 139 through 148). In the illustrated embodiment, the first chunk of data 462 includes 10% of data from the second chunk of data 464, and the second chunk of data 464 includes 10% of data from the first chunk of data 462. Therefore, in this example, each chunk of data may include 10% of data from another chunk of data. The percentage of data may be determined by context and a limit of a LLM (e.g., the LLM server 218). As mentioned above, headers from the table may remain in each chunk. For example, the first chunk of data 462 may include ten data entries with the headers and the second chunk of data 464 may include ten data entries with the headers.

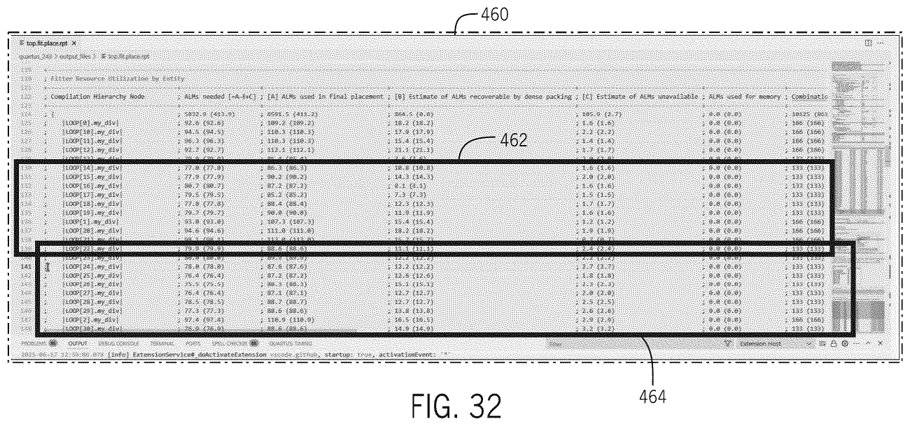

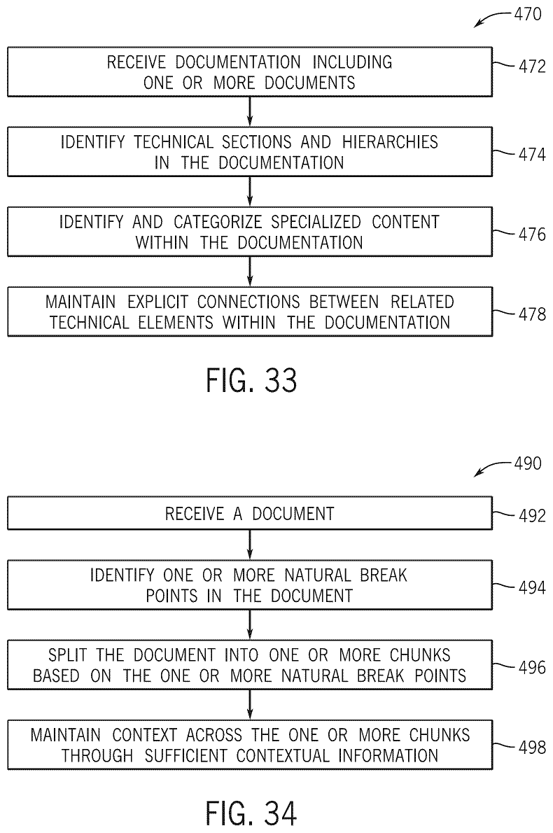

FIG. 33 is a flowchart of an example method 470 for FPGA-aware document analysis of the recursive document splitting and chunking system 152 of FIG. 29. For example, the design assistant 30 may receive documentation including one or more documents (block 472).

The design assistant 30 may identify technical sections and hierarchies in the documentation (block 474). For example, the design assistant 30 may employ specialized algorithms that recognize a unique structure of FPGA documentation. The specialized algorithms may automatically detect section boundaries, technical diagrams, and hierarchical relationships within provided content.

The design assistant 30 may identify and categorize specialized content within the documentation (block 476). In some embodiments, the design assistant 30 may identify and categorize specialized content within the documentation using FPGA terminology and document tags. For example, the design assistant 30 may recognize FPGA-specific content patterns. In some embodiments, the specialized content may include device information, resource utilization tables, IP parameterization information, and the like.

The design assistant 30 may maintain explicit relationships (e.g., connections) between related technical elements within the documentation (block 478). For example, the design assistant 30 may preserve relationships between technical concepts. Therefore, the design assistant 30 may ensure that interdependent concepts remain linked even after document splitting.

The method 470 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 470 may be performed by separate systems or devices.

FIG. 34 is a flowchart of an example method 490 for a recursive splitting algorithm of the recursive document splitting and chunking system 152 of FIG. 29. For example, the design assistant 30 may receive a document (block 492).

The design assistant 30 may identify one or more break points (e.g., natural break points) in the document (block 494). In some embodiments, the design assistant 30 may identify one or more natural break points in the content of the document based on semantic meaning and technical context. For example, the design assistant 30 may intelligently break documents at logical boundaries. Unlike traditional fixed-size chunking, the design assistant 30 may identify natural break points in content based on semantic meaning and technical context. Therefore, the design assistant 30 may create more coherent information units. For example, the natural break points may include breaks defined by subsections within a document.

The design assistant 30 may split the document into one or more chunks based on the one or more break points (e.g., natural break points) (block 496). The design assistant 30 may maintain context across split points. Each chunk may contain sufficient contextual information to be understood independently, while also preserving references to a parent document and related chunks.

The design assistant 30 may maintain context across the one or more chunks through sufficient contextual information (block 498). In some embodiments, the sufficient contextual information may be analyzed independently. Additionally, or alternatively, the design assistant 30 may handle nested technical information. For example, the design assistant 30 process deeply nested technical content, such as hierarchical design descriptions or multi-level timing reports, without losing structural integrity.

The method 490 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 490 may be performed by separate systems or devices.

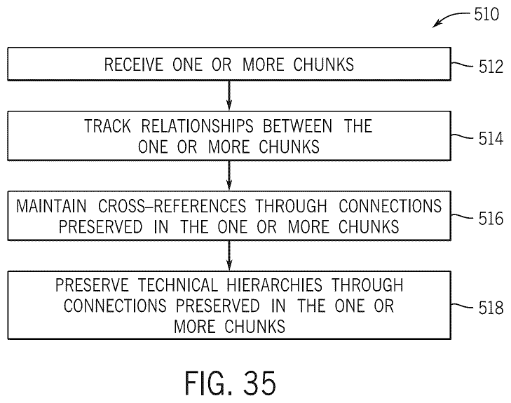

FIG. 35 is a flowchart of an example method 510 for a context preservation system of the recursive document splitting and chunking system 152 of FIG. 29. For example, the design assistant 30 may receive one or more chunks (block 512). As described above, a chunk may include a portion of data which may include overlapping data with a preceding chunk, a following chunk, or both.

The design assistant 30 may track relationships between the one or more chunks (block 514). In some embodiments, the design assistant 30 may track relationships between the one or more chunks by maintaining a comprehensive graph of relationships between document fragments. Therefore, the design assistant 30 may enable navigation between related content pieces during information retrieval.

The design assistant 30 may maintain cross-references through relationships (e.g., connections) preserved in the one or more chunks (block 516). For example, when documents reference other sections or external resources, relationships (e.g., connections) may be preserved in a chunked representation, allowing for complete analysis of interdependent information.

The design assistant 30 may preserve technical hierarchies through relationships (e.g., connections) preserved in the one or more chunks (block 518). For example, an original hierarchical structure of FPGA documentation may be maintained in the chunked representation, ensuring that parent-child relationships between technical concepts remain intact.

The method 510 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 510 may be performed by separate systems or devices.

FIG. 36 is an illustration of an example of a table chunking relationship 530 associated with the design assistant 30 of FIG. 29. As illustrated, a table may be split into four chunks including a first chunk 532, a second chunk 534, a third chunk 536, and a fourth chunk 538. As mentioned above, each chunk may include data from another chunk. For example, each chunk may include a percentage (e.g., 1%, 5%, 10%, 15%, 20%, 30%) of data from a previous chunk and a following chunk. The percentage of data may be determined by context and a limit of a LLM (e.g., the LLM server 218). It should be noted that each chunk may have the same or different size compared to other chunks. For example, contextual chunking may result in uneven sizes of chunks.

As illustrated, the first chunk 532 may include a portion of data 540 from the second chunk 534. The second chunk 534 may include a portion of data 542 from the first chunk 532 and a portion of data 544 from the third chunk 536. The third chunk may include a portion of data 546 from the second chunk 534 and a portion of data 548 from the fourth chunk 538. The fourth chunk 538 may include a portion of data 550 from the first chunk 532. Therefore, an initial chunk (e.g., the first chunk 532) and a final chunk (e.g., the fourth chunk 538) may include data from one following and preceding chunk, respectively. Each middle chunk (e.g., the second chunk 534 and the third chunk 536) may include data from both a preceding chunk and a following chunk.

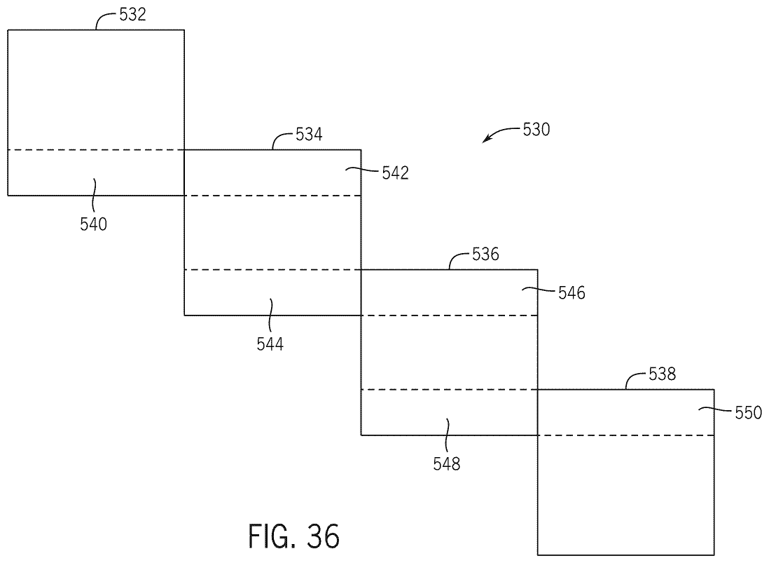

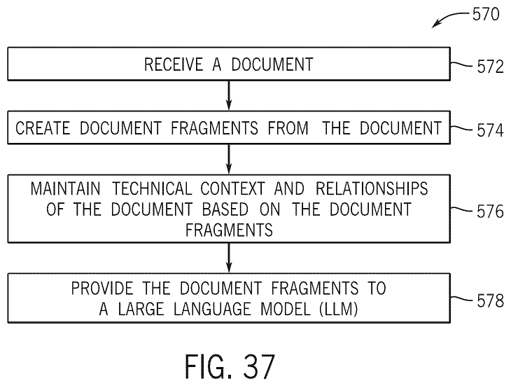

FIG. 37 is a flowchart of an example method 570 for integration with RAG systems of the recursive document splitting and chunking system 152 of FIG. 29. For example, the design assistant 30 may receive a document (block 572).

The design assistant 30 may create document fragments from the document (block 574). In some embodiments, the document fragments may be sized and structured for LLM comprehension. For example, the design assistant 30 may optimize chunks for LLM processing. In some embodiments, the design assistant 30 may balance context preservation with processing efficiency.

The design assistant 30 may maintain technical context and relationships of the document based on the document fragments (block 576). The design assistant 30 may enhance retrieval accuracy. By maintaining technical context and relationships, the design assistant 30 may significantly improve relevance of search results when the designer (e.g., user) submits a user query (e.g., the user prompt 206) for specific FPGA information.

The design assistant 30 may provide the document fragments to an LLM (block 578). The design assistant 30 may maintain technical context for AI assistance. Preserving relationships and hierarchies may enable AI systems to provide more accurate and contextually appropriate assistance for FPGA design tasks.

The method 570 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 570 may be performed by separate systems or devices.

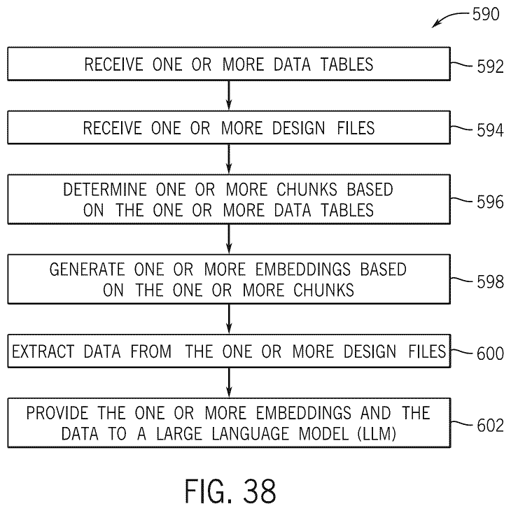

FIG. 38 is a flowchart of an example method 590 for the recursive document splitting and chunking system 152 of FIG. 29. For example, the design assistant 30 may receive one or more data tables (block 592). The one or more data tables may include the project data table 182 and the report data table 190.

The design assistant 30 may receive one or more design files (block 594). The one or more design files may include the design project files 184 and the design report files 192.

The design assistant 30 may determine one or more chunks based on the one or more data tables (block 596). In some embodiments, the one or more chunks may be determined in the recursive text splitter based chunking 186 and the table-based chunking 194.

The design assistant 30 may generate one or more embeddings based on the one or more chunks (block 598). As described above, embeddings may be created through the process of converting a numerical representation of data (e.g., text, images, or audio) into a high-dimensional vector (e.g., an array of numbers). For example, the one or more embeddings may be generated in the chunking process 188 and the table process 196.

The design assistant 30 may extract data from the one or more design files (block 600). As mentioned above, the one or more design files may include the design project files 184 and the design report files 192.

The design assistant 30 may provide the one or more embeddings and the data to the LLM (block 602). In some embodiments, the design assistant 30 may provide the one or more embeddings and the data to the LLM server 218.

The method 590 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 590 may be performed by separate systems or devices.

FIG. 39 is a block diagram of the design history integration system 154 of the design assistant 30 of FIG. 15. In some embodiments, the design history integration system 154 may integrate design history into a development workflow. Therefore, the design history integration system 154 may enable efficient retrieval and analysis of historical design data through natural language queries. The design history integration system 154 may track design iterations, conversation history, identify patterns, and help prevent repeated issues.

The design history integration system 154 may accelerate design closure by helping the designer (e.g., user) to learn from past iterations and avoid repeated mistakes. The design history integration system 154 may enhance design software tools (e.g., Quartus® Exploration Dashboard) with natural language interfaces and historical trend analysis. As a result, the designer (e.g., user) may achieve design closure with fewer iterations.

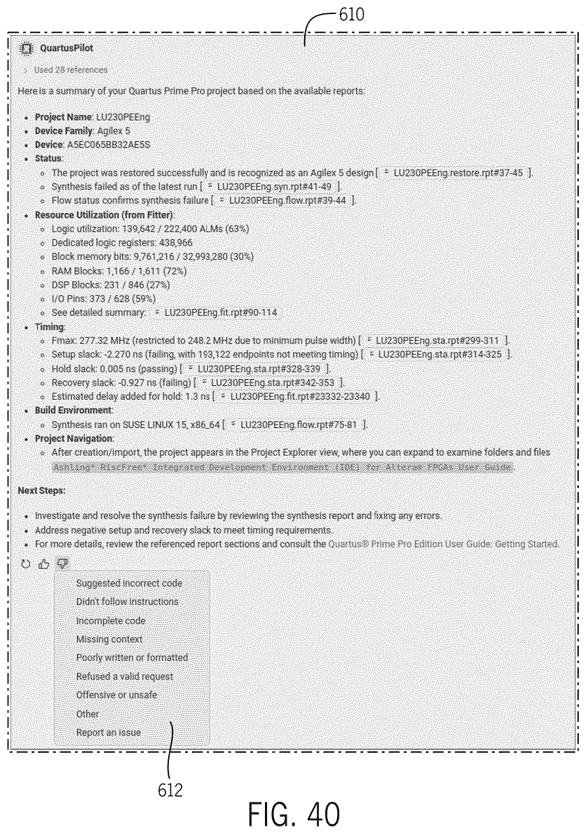

FIG. 40 is an illustration of an example of historical design software data collection 610 associated with the design assistant 30 of FIG. 15. For example, historical design software data (e.g., Quartus® design data) may include data from multiple runs over time. Additionally, or alternatively, the design software design data may include data from multiple revisions of a project. The historical design software data may be stored in the history data table 198.

In some embodiments, the historical design software data collection 610 may include which revision the data belongs to (e.g., revision A, revision B). The historical data collection 610 may include if there are multiple runs for the design software project (e.g., a Quartus® Project). The historical data may be categorized based on multiple runs. The historical data may provide a better analysis of what changed from run to run to help the designer (e.g., user) to analyze changes made and implications from the changes in final results. Additionally, or alternatively, user conversation data (e.g., the chat conversation history 200) may help retrieve or maintain conversation context for long conversations.

The design assistant 30 may provide a functionality for the designer (e.g., user) to provide feedback on responses from the design assistant 30. The feedback may help reduce or eliminate wrong responses and improve future responses. Additionally, or alternatively, the design assistant 30 may learn from issues that have been reported. For example, the designer (e.g., user) may indicate if the feedback is positive (e.g., thumbs up) or negative (e.g., thumbs down). The thumbs down may include a pop-up menu 612. In some embodiments, if the user reports a thumbs down on a response, then the response may be discarded, and also avoided in the future.

In some embodiments, the design assistant 30 may track if the designer (e.g., user) accepts suggested code to be implanted into current code of the design. Additionally, or alternatively, the design assistant 30 may track if the designer (e.g., user) modified a portion of the suggested code. The design assistant 30 may track information about the designer (e.g., user) across different designs to incorporate user preferences. For example, the design assistant 30 may include a home directory that may be accessible across multiple design sessions of one design and/or across multiple designs. In some embodiments, the home directory may be stored on a local device (e.g., user device). Additionally, or alternatively, at least a portion of the home directory may be located on a cloud.

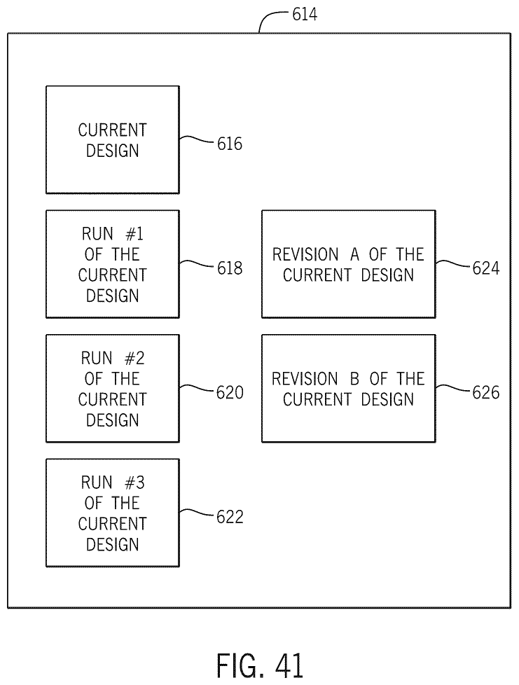

FIG. 41 is an illustration of an example of a design evolution 614 associated with the design assistant 30 of FIG. 15. For example, a current design 616 may be associated with a project selected by the designer (e.g., user). The design evolution 614 may include data from previous revisions and/or runs such as the data from the historical data collection 610. As illustrated, the design evolution 614 may include data from a first run 618 of the current design 616, a second run 620 of the current design 616, and a third run 622 of the current design 616. Additionally or alternatively, the design evolution 614 may include data from a revision A 624 of the current design 616 and a revision B 626 of the current design 616.

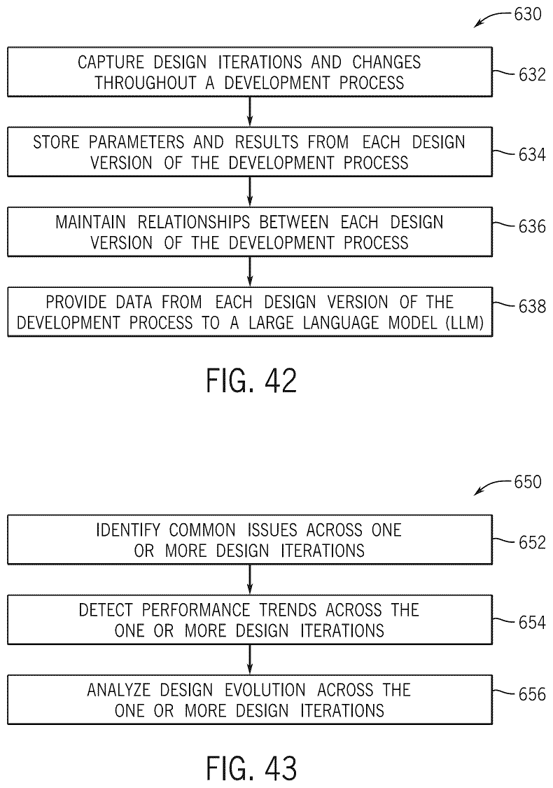

FIG. 42 is a flowchart of an example method 630 for historical data tracking of the design history integration system 154 of FIG. 39. For example, the design assistant 30 may capture design iterations and changes throughout a development process (block 632). In some embodiments, the design software (e.g., Quartus®) may provide a history (e.g., the history data table 198) to a database used by the design assistant 30.

The design assistant 30 may store parameters and results from each design version of the development process (block 634). In some embodiments, the parameters may be technical parameters.

The design assistant 30 may maintain relationships between each design version of the development process (block 636). In some embodiments, the design assistant 30 may maintain relationships between different design versions of the development process.

The design assistant 30 may provide data from each design version of the development process to an LLM (block 638). In some embodiments, the LLM may be the LLM server 218.

The method 630 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 630 may be performed by separate systems or devices.

FIG. 43 is a flowchart of an example method 650 for a pattern recognition system of the design history integration system 154 of FIG. 39. For example, the design assistant 30 may identify common issues across one or more design iterations (block 652).

The design assistant 30 may detect performance trends across the one or more design iterations (block 654). For example, the design assistant 30 may analyze multiple design iterations of one design to identify performance trends.

The design assistant 30 may analyze design evolution across the one or more design iterations (block 656). In some embodiments, the design assistant 30 may analyze the design evolution across the multiple design iterations to provide insights into development patterns.

The method 650 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 650 may be performed by separate systems or devices.

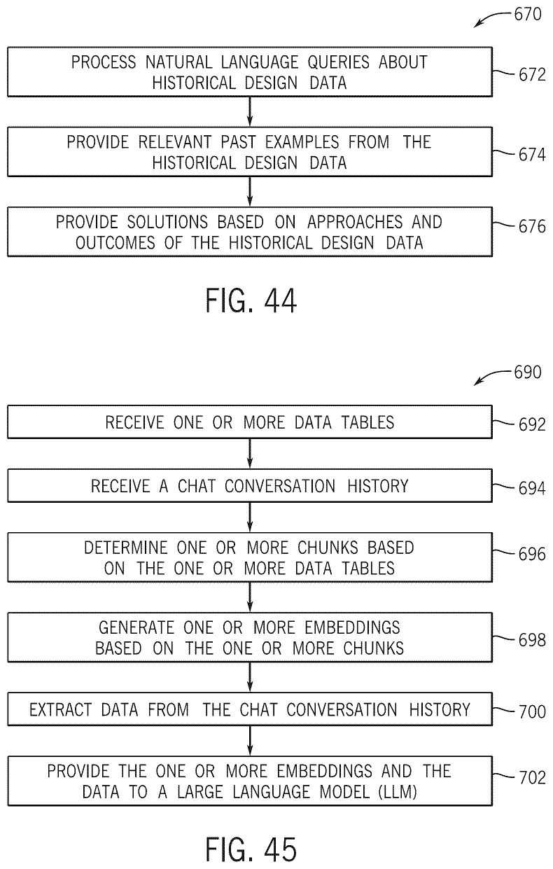

FIG. 44 is a flowchart of an example method 670 for a natural language interface of the design history integration system 154 of FIG. 39. For example, the design assistant 30 may process natural language queries about historical design data (block 672).

The design assistant 30 may provide relevant past examples from the historical design data (block 674). In some embodiments, the relevant past examples from the historical design data may match current design challenges.

The design assistant 30 may provide solutions based on approaches and outcomes of the historical design data (block 676). In some embodiments, the solutions may be based on a previous solution to a similar query.

The method 670 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 670 may be performed by separate systems or devices.

FIG. 45 is a flowchart of an example method 690 for the design history integration system 154 of FIG. 39. For example, the design assistant 30 may receive one or more data tables (block 692). The one or more data tables may include the history data table 198.

The design assistant 30 may receive a chat conversation history (block 694). In some embodiments, the chat conversation history may include the chat conversation history 200.

The design assistant 30 may determine one or more chunks based on the one or more data tables (block 696). In some embodiments, the one or more chunks may be determined in the recursive text splitter based chunking 202.

The design assistant 30 may generate one or more embeddings based on the one or more chunks (block 698). For example, the one or more embeddings may be generated in the chunking process 204.

The design assistant 30 may extract data from the chat conversation history (block 700). As mentioned above, the chat conversation history may include the chat conversation history 200.

The design assistant 30 may provide the one or more embeddings and the data to an LLM (block 702). In some embodiments, the LLM may include the LLM server 218.

The method 690 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 690 may be performed by separate systems or devices.

The design history integration system 154 may operate through a series of interconnected processes. The design history integration system 154 may begin by tracking design iterations and changes throughout a development process. The design history integration system 154 may analyze patterns and trends across multiple design versions. The design history integration system 154 may process natural language queries to make historical data accessible, providing historical context for current design decisions. Finally, the design history integration system 154 may suggest improvements based on insights derived from past design data. In some embodiments, the design history integration system 154 may suggest subsequent queries during a conversation with the designer (e.g., user) based on most recent queries provided by the designer (e.g., user).

FIG. 46 is a block diagram of the dynamic scoping system 156 of the design assistant 30 of FIG. 15. In some embodiments, the dynamic scoping system 156 may intelligently determine which FPGA tool outputs and documentation to search based on a user's query (e.g., the user prompt 206) and context. The dynamic scoping system 156 may use slash commands (e.g., @QuartusPilot/IP_Parameters) and context analysis to optimize search scope and improve result relevance.

The dynamic scoping system 156 may significantly improve search efficiency by automatically focusing on relevant tool outputs and documentation. The designer (e.g., user) may find specific information more quickly, and the dynamic scoping system 156 may reduce noise from irrelevant results.

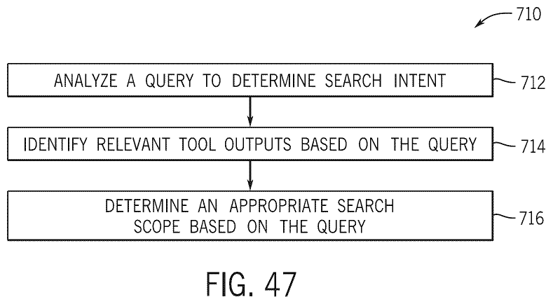

FIG. 47 is a flowchart of an example method 710 for a scope analysis system of the dynamic scoping system 156 of FIG. 46. For example, the design assistant 30 may analyze a query to determine search intent (block 712).

The design assistant 30 may identify relevant tool outputs based on the query (block 714). In some embodiments, the query may be the user prompt 206.

The design assistant 30 may determine an appropriate search scope based on the query (block 716). Additionally, or alternatively, the appropriate search scope may be based on context of the query.

The method 710 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 710 may be performed by separate systems or devices.

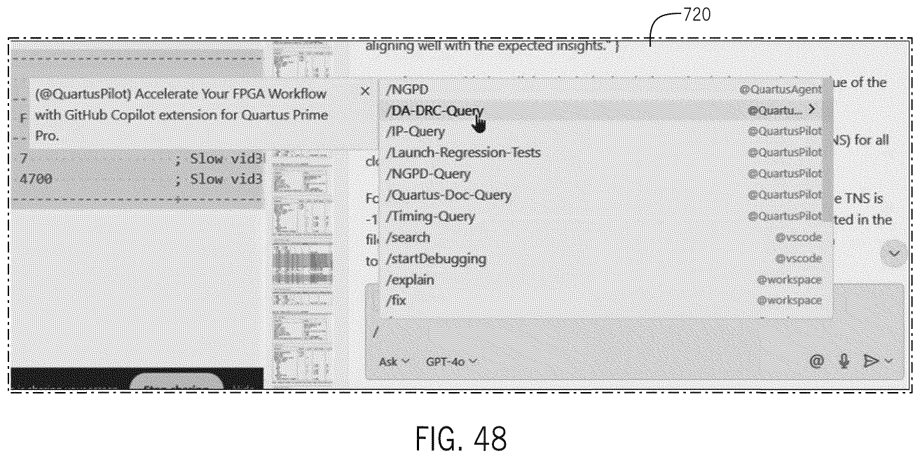

FIG. 48 is an illustration of an example of slash commands 720 associated with the design assistant 30 of FIG. 15. For example, a slash command (e.g., /command) may be used to implement a command (e.g., open a file). As illustrated, some slash commands may include /NGPD, /DA-DRC-Query, /IP-Query, /Launch-Regression-Tests, /NGPD-Query, /Quartus-Doc-Query, /Timing-Query, /search, /startDebugging, /explain, /fix, and so on. These slash commands with keywords provide additional assistance to the LLM to retrieve contextual information related the query provided by the designer/user.

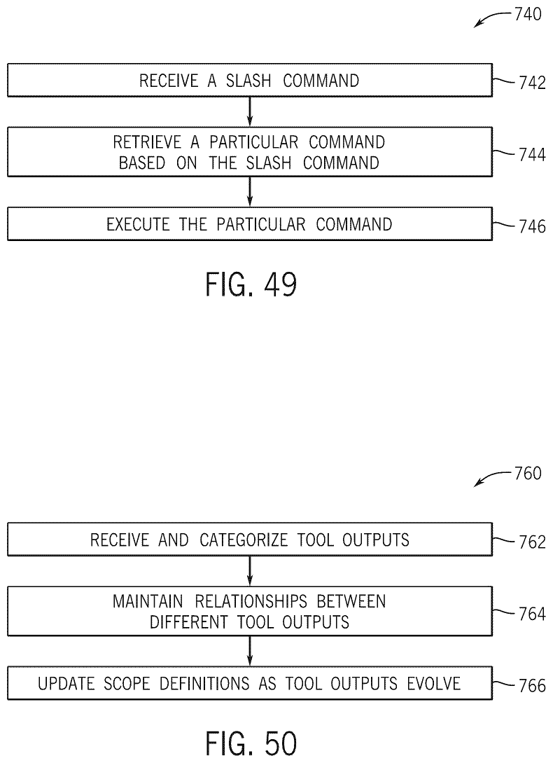

FIG. 49 is a flowchart of an example method 740 for command processing of the dynamic scoping system 156 of FIG. 46. For example, the design assistant 30 may receive a slash command (block 742).

The design assistant 30 may retrieve a particular command based on the slash command (block 744). In some embodiments, the slash command may include the particular command (e.g., /particular-command).

The design assistant 30 may execute the particular command (block 746). As mentioned above, the slash command may be used to implement the particular command.

The method 740 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 740 may be performed by separate systems or devices.

FIG. 50 is a flowchart of an example method 760 for file type management of the dynamic scoping system 156 of FIG. 46. For example, the design assistant 30 may receive and categorize tool outputs (block 762). In some embodiments, the design assistant 30 may categorize the tool outputs by type and purpose.

The design assistant 30 may maintain relationships between different tool outputs (block 764). In some embodiments, the design assistant 30 may maintain relationships between different file types and their relevance.

The design assistant 30 may update scope definitions as tool outputs evolve (block 766). In some embodiments, the tool outputs may evolve overtime, therefore scope and relations may change.

The method 760 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 760 may be performed by separate systems or devices.

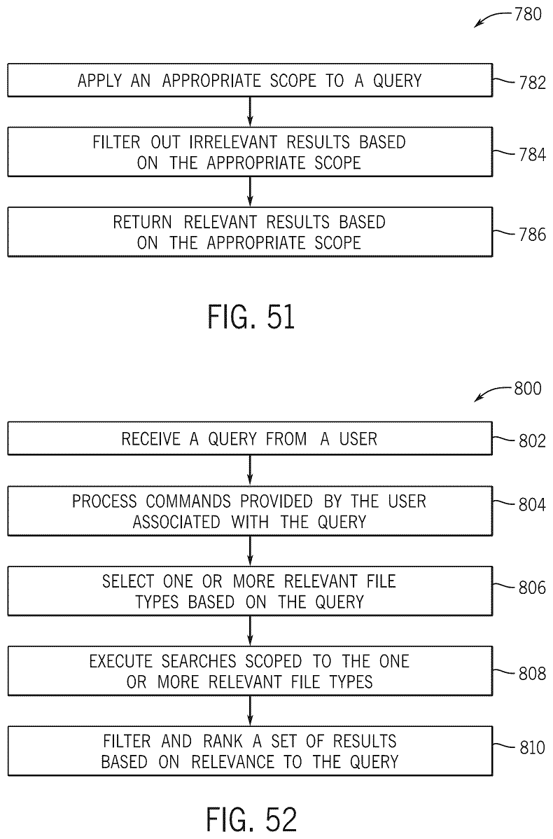

FIG. 51 is a flowchart of an example method 780 for a context-aware search of the dynamic scoping system 156 of FIG. 46. For example, the design assistant 30 may apply an appropriate scope to a query (block 782). In some embodiments, the design assistant 30 may determine the appropriate scope.

The design assistant 30 may filter out irrelevant results based on the appropriate scope (block 784). For example, the irrelevant results may pertain to scope outside the appropriate scope.

The design assistant 30 may return relevant results based on the appropriate scope (block 786). For example, the relevant results may pertain to scope inside the appropriate scope.

The method 780 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 780 may be performed by separate systems or devices.

FIG. 52 is a flowchart of an example method 800 for the dynamic scoping system 156 of FIG. 46. For example, the design assistant 30 may receive a query from a user (block 802). Additionally or alternatively, the design assistant 30 may receive context to analyze an intent of the query.

The design assistant 30 may process commands provided by the user associated with the query (block 804). In some embodiments, the design assistant 30 may determine if the commands provided by the user are related to a scope of the query.

The design assistant 30 may select one or more relevant file types based on the query (block 806). In some embodiments, the design assistant 30 may select the one or more relevant file types from a list of file types.

The design assistant 30 may execute searches scoped to the one or more relevant file types (block 808). In some embodiments, the design assistant 30 may tailor a search based on the one or more relevant file types.

The design assistant 30 may filter and rank a set of results based on relevance to the query (block 810). For example, the design assistant 30 may only include a portion (e.g., top 3, top 5, top 10) of the set of results.

The method 800 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 800 may be performed by separate systems or devices.

The dynamic scoping system 156 may operate through a series of integrated steps. The dynamic scoping system 156 may begin by analyzing user queries and their context to analyze an intent. The dynamic scoping system 156 then may process any scope-related commands provided by the designer (e.g., user). Next, the dynamic scoping system 156 may select relevant file types based on the analysis. The dynamic scoping system 156 may execute searches scoped to the relevant file types. Finally, the dynamic scoping system 156 may filter and rank results based on relevance to an original query (e.g., the user prompt 206).

FIG. 53 is a block diagram of the cross-referencing system 158 of the design assistant 30 of FIG. 15. In some embodiments, the cross-referencing system 158 may intelligently link FPGA documentation, design report files, source code, and successful chat history. The cross-referencing system 158 may enable the designer (e.g., user) to trace a lineage of design decisions and LLM generated results back to source information. The traceability may provide context for why specific recommendations were made and how they relate to existing documentation, reports, and code.

The cross-referencing system 158 may accelerate design and development by providing comprehensive cross-referencing across all relevant information sources. The designer (e.g., user) may analyze a rationale behind LLM generated results by tracing back to source documentation, reports, code, and successful chat interactions that informed the LLM generated results. The traceability may improve confidence in AI-assisted design decisions and facilitates knowledge transfer to the designer (e.g., user).

The design assistant 30 may provide functionality to cross referencing a response to user data or documentation data sources that were being used as additional context to provide the user a final response. The designer (e.g., user) may cross reference data within a design software (e.g., Quartus®) project directory or a provided documentation link. The provided documentation link may improve confidence in a response provided to the user. For example, the user may cross reference a response against various sources used.

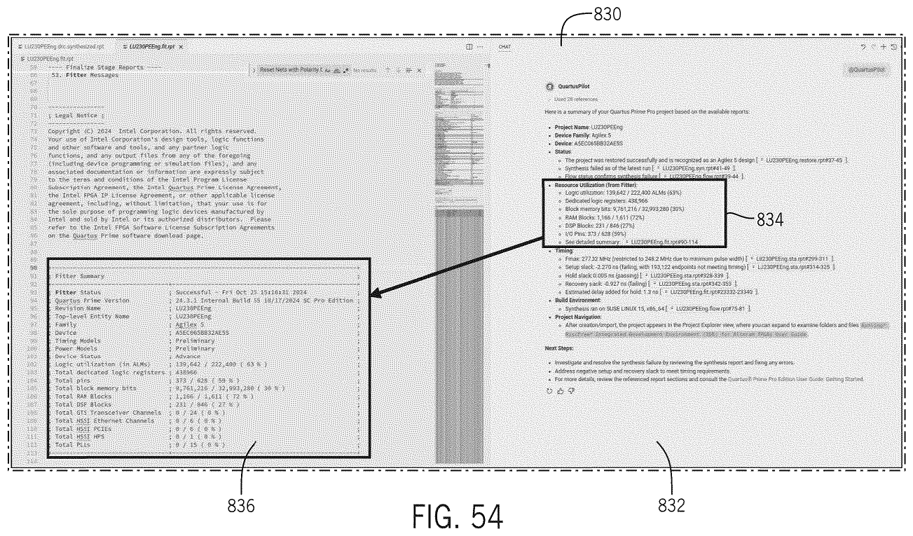

FIG. 54 is an illustration of an example of cross referencing design software (e.g., Quartus®) data 830 associated with the design assistant 30 of FIG. 15. A provided response 832 may be backed by a file path along with a line number that may be cross referenced. For example, a portion 834 of the provided response 832 may be cross referenced to a portion 836 of the file path.

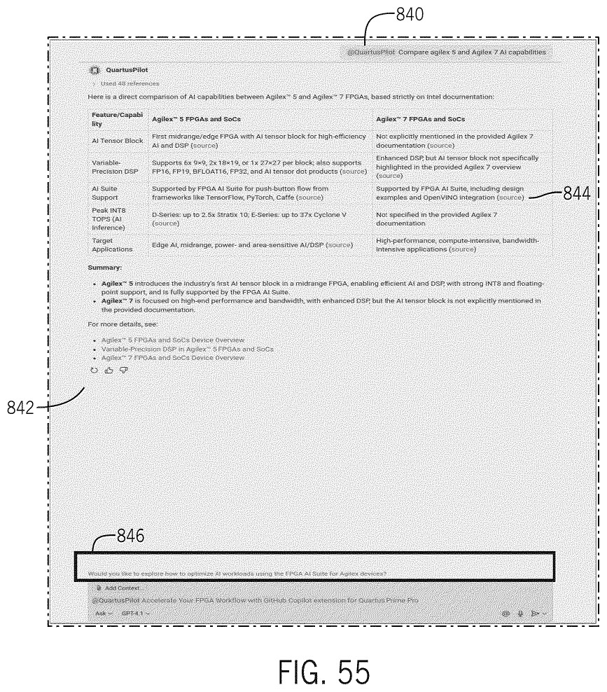

FIG. 55 is an illustration of an example of cross referencing documentation data sources 840 associated with the design assistant 30 of FIG. 15. As illustrated, an example response 842 may include documentation source links 844. For example, the documentation source links 844 may include a hyperlink with display text (e.g., source). The designer (e.g., user) may click the documentation source links 844 to validate the example response 842 or to get more information.

In some embodiments, the design assistant 30 may provide a follow up suggestion 846 that may help the designer (e.g., user) to identify what can be queried next or what to get help with. As illustrated, the follow up suggestion 846 may suggest “Would you like to explore how to optimize AI workloads using the FPGA AI Suite for Agilex devices?”

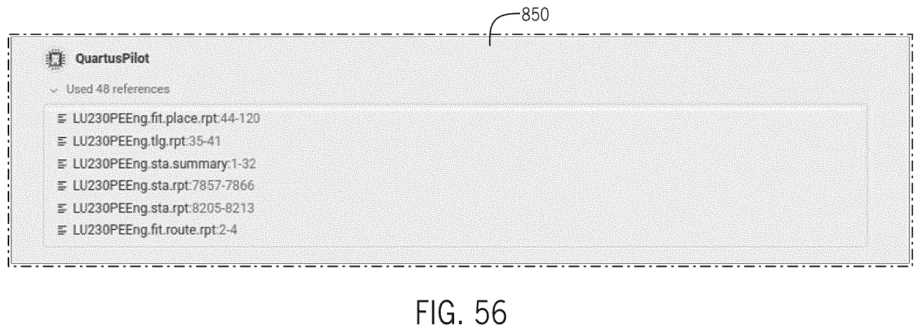

FIG. 56 is an illustration of an example of relevant references 850 associated with the design assistant 30 of FIG. 15. The design assistant may provide references for data from a design software project (e.g., Quartus® Project) used to curate a response. The references may provide transparency to the designer (e.g., user) about how user data was handled and used during a response creation.

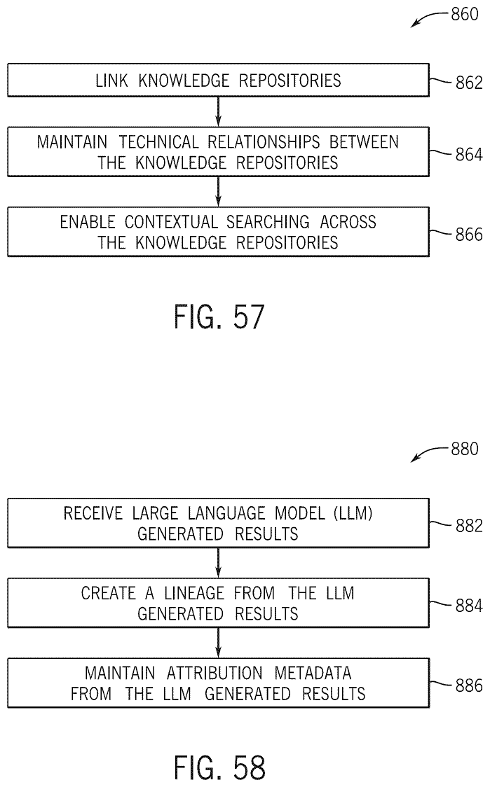

FIG. 57 is a flowchart of an example method 860 for a cross-reference engine of the cross-referencing system 158 of FIG. 53. For example, the design assistant 30 may link knowledge repositories (block 862). In some embodiments, the knowledge repositories may include documentation, design reports, source code, and chat history.

The design assistant 30 may maintain technical relationships between the knowledge repositories (block 864). In some embodiments, the design assistant 30 may maintain technical relationships between the documentation, the design reports, the source code, and the chat history.

The design assistant 30 may enable contextual searching across the knowledge repositories (block 866). In some embodiments, the design assistant 30 may enable contextual searching across multiple knowledge repositories with bidirectional navigation.

The method 860 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 860 may be performed by separate systems or devices.

FIG. 58 is a flowchart of an example method 880 for a source attribution system of the cross-referencing system 158 of FIG. 53. For example, the design assistant 30 may receive LLM generated results (block 882).

The design assistant 30 may create a lineage from the LLM generated results (block 884). In some embodiments, the lineage may include the LLM generated results back to source documentation, reports, code, and conversations.

The design assistant 30 may maintain attribution metadata from the LLM generated results (block 886). In some embodiments, the design assistant 30 may maintain attribution metadata to explain why specific recommendations were made in the LLM generated results.

The method 880 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 880 may be performed by separate systems or devices.

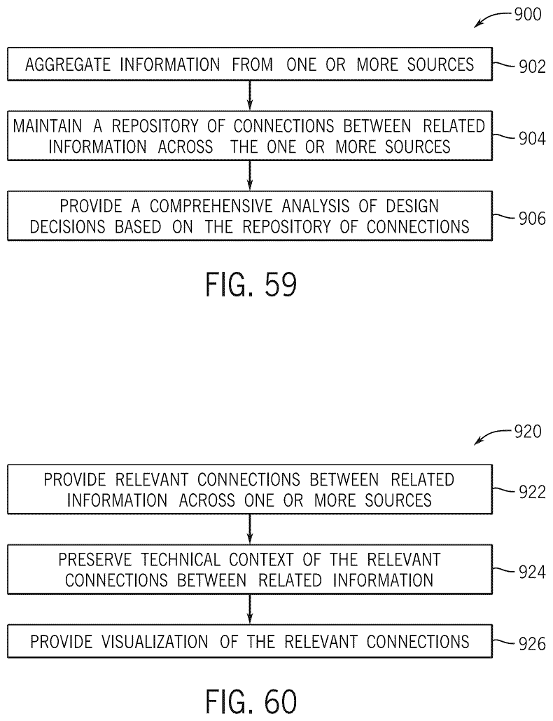

FIG. 59 is a flowchart of an example method 900 for a knowledge integration system of the cross-referencing system 158 of FIG. 53. For example, the design assistant 30 may aggregate information from one or more sources (block 902). In some embodiments, the different sources may include documentation, design reports, source code, successful chat interaction, and so on.

The design assistant 30 may maintain a repository of relationships (e.g., connections) between related information across the one or more sources (block 904). As mentioned above, the different sources may include documentation, design reports, source code, successful chat interaction, and so on.

The design assistant 30 may provide a comprehensive analysis of design decisions based on the repository of relationships (e.g., connections) (block 906). In some embodiments, the comprehensive analysis may include documentation analysis, design report analysis, source code analysis, successful chat interaction analysis, and so on.

The method 900 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 900 may be performed by separate systems or devices.

FIG. 60 is a flowchart of an example method 920 for context-aware visualization of the cross-referencing system 158 of FIG. 53. For example, the design assistant 30 may provide relevant relationships (e.g., connections) between related information across one or more sources (block 922). In some embodiments, the different sources may include documentation, design reports, source code, successful chat interaction, and so on.

The design assistant 30 may preserve technical context of the relevant relationships (e.g., connections) between related information (block 924). In some embodiments, the design assistant 30 may preserve technical context of each reference and its relationship to others.

The design assistant 30 may provide visualization of the relevant relationships (e.g., connections) (block 926). For example, as illustrated in FIG. 54, the portion 834 of the provided response 832 may be cross referenced to the portion 836 of the file path.

The method 920 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 920 may be performed by separate systems or devices.

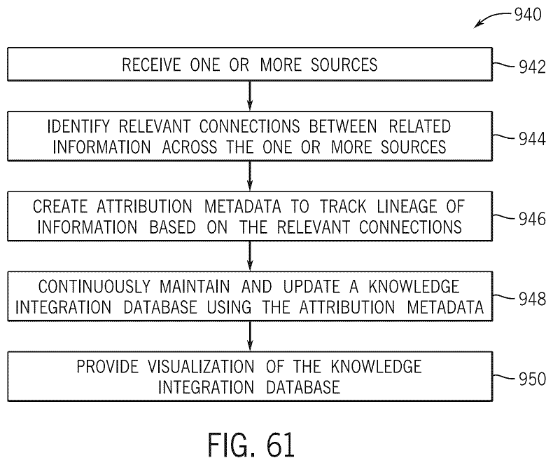

FIG. 61 is a flowchart of an example method 940 for the cross-referencing system 158 of FIG. 53. For example, the design assistant 30 may receive one or more sources (block 942). In some embodiments, the sources include documentation, design reports, source code, chat history data, and so on.

The design assistant 30 may identify relevant relationships (e.g., connections) between related information across the one or more sources (block 944). As mentioned above, the sources may include documentation, design reports, source code, chat history data, and so on.

The design assistant 30 may create attribution metadata to track lineage of information based on the relevant relationships (e.g., connections) (block 946). In some embodiments, the attribution metadata may be stored in the design assistant 30.

The design assistant 30 may continuously maintain and update a knowledge integration database using the attribution metadata (block 948). In some embodiments, the knowledge integration database may be stored in the design assistant 30.

The design assistant 30 may provide visualization of the knowledge integration database (block 950). In some embodiments, the design assistant 30 may provide visualization via hyperlinks that enable the designer (e.g., user) to trace origins of LLM generated results.

The method 940 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 940 may be performed by separate systems or devices.

The cross-referencing system 158 may operate through a comprehensive workflow. The cross-referencing system 158 may begin by processing documentation, design reports, source code, and chat history data. The cross-referencing system 158 then may identify relevant relationships (e.g., connections) between related information across these sources. Attribution metadata may be created to track the lineage of information. The cross-referencing system 158 may continuously maintain and update the knowledge integration database. Finally, the cross-referencing system 158 may provide visualization via hyperlinks that enable the designer (e.g., user) to trace the origins of LLM generated results.

In some embodiments, the MCP based agent system 162 may extend AI assistants with realtime access to FPGA design tool-specific information sources, which may be further described below with reference to FIG. 62. Therefore, the MCP based agent system 162 may enable contextually aware assistance across an entire FPGA design workflow. The MCP based agent system 162 may provide a suite of specialized agents that may retrieve and process documentation, IP information, project files, design reports, and the like to deliver accurate and up-to-date guidance tailored to specific design tasks.

The MCP based agent system 162 may significantly improve FPGA design productivity by providing the designer (e.g., user) with intelligent, context-aware assistance that analyzes EDA tool-specific workflows and may access most current information. In some embodiments, an MCP architecture may enable seamless integration of specialized agents with LLMs. The MCP based agent system 162 may create an extensible system that may evolve alongside FPGA design tools while maintaining accuracy and relevance.

With that in mind, FIG. 62 is an illustration of an example of MCP tools 960 within the MCP based agent system 162 of the design assistant 30 of FIG. 15. As illustrated, the MCP tools 960 may include search-quartus-doc, search-quartus-ip-info, and search-quartus-ip-param-info. The MCP tools 960 may assist the designer (e.g., user) with FPGA development using design software (e.g., Quartus®). In some embodiments, the MCP based agent system 162 may include additional MCP tools such as a searchQuartusDoc tool, a searchQuartusTemplates tool, a searchQuartusGitHubRepo tool, a searchQuartuslPInfo tool, a searchQuartuslPParamInfo tool, a searchQuartusIPInterfaceInfo tool, a searchQuartusProject tool, and a searchQuartusProjectReports tool.

For the searchQuartusDoc tool, the MCP based agent system 162 may retrieve the most up-to-date information from a design software (e.g., Quartus®) documentation database (e.g., the design software (e.g., Quartus®) documentation 166) based on a user query (e.g., the user prompt 206). Since knowledge from an LLM (e.g., the LLM server 218) may be outdated, the designer (e.g., user) may use the searchQuartusDoc tool to access the latest details on design software (e.g., Quartus® Prime Pro) usage, IP documentation, device features, tool workflows, and the like. The designer (e.g., user) may ensure accurate guidance by always consulting the searchQuartusDoc tool for the most current insights.

For the searchQuartusTemplates tool, the MCP based agent system 162 may retrieve the most up-to-date information from a design software (e.g., Quartus®) Template database based on a user query (e.g., the user prompt 206). Since knowledge from an LLM (e.g., the LLM server 218) may be outdated, the designer (e.g., user) may use the searchQuartusTemplates tool to access the latest details about various templates available in design software (e.g., Quartus®). In some embodiments, the design software (e.g., Quartus®) Template database may include templates for RTL development using Verilog, SystemVerilog and VHDL. Additionally, or alternatively, the design software (e.g., Quartus®) Template database may include other templates in a tcl and/or a sdc format. The designer (e.g., user) may ensure accurate guidance by always consulting the searchQuartusTemplates tool for the most current insights about available templates in design software (e.g., Quartus®).

For the searchQuartusGitHubRepo tool, the MCP based agent system 162 may retrieve the most up-to-date information from a design software (e.g., Quartus®) example design database. The design software (e.g., Quartus®) example design database may be created from a GitHub repo based on a user query (e.g., the user prompt 206). Since knowledge from an LLM (e.g., the LLM server 218) may be outdated, the designer (e.g., user) may use the searchQuartusGitHubRepo tool to access the latest example designs available in design software (e.g., Quartus®). The design software (e.g., Quartus®) example design database may include complete downloadable examples for creating various design software (e.g., Quartus®) based designs. The designer (e.g., user) may ensure accurate guidance by always consulting the searchQuartusGitHubRepo tool for the most current insights about available example designs and samples in design software (e.g., Quartus®).

For the searchQuartuslPInfo tool, the MCP based agent system 162 may retrieve the most up-to-date information from a design software (e.g., Quartus®) IP documentation database based on a user query (e.g., the user prompt 206). Since knowledge from an LLM (e.g., the LLM server 218) may be outdated, the designer (e.g., user) may use the searchQuartusIPInfo tool to access the latest details on design software (e.g., Quartus® Prime Pro) IP information such as IP name, display name, version, category, supported device families, and the like. The designer (e.g., user) may ensure accurate guidance by always consulting the searchQuartusIPInfo tool for the most current insights.

For the searchQuartuslPParamInfo tool, the MCP based agent system 162 may retrieve the most up-to-date information from a design software (e.g., Quartus®) IP parameter documentation database based on a user query (e.g., the user prompt 206). Since knowledge from an LLM (e.g., the LLM server 218) may be outdated, the designer (e.g., user) may use the searchQuartuslPParamInfo tool to access the latest details on design software (e.g., Quartus® Prime Pro) IP parameter information such as parameter names, default value, type, allowed range, and the like. The designer (e.g., user) may ensure accurate guidance by always consulting the searchQuartuslPParamInfo tool for the most current insights. In some embodiments, the searchQuartuslPParamInfo tool may work better with an IP name identified from the searchQuartuslPInfo tool.

For the searchQuartusIPInterfaceInfo tool, the MCP based agent system 162 may retrieve the most up-to-date information from a design software (e.g., Quartus®) IP interface documentation database based on a parameter (e.g., matchString). Since knowledge from an LLM (e.g., the LLM server 218) may be outdated, the designer (e.g., user) may use the searchQuartusIPInterfaceInfo tool to access the latest details on design software (e.g., Quartus® Prime Pro) IP interface information such as such as interface name, type, direction, associated clock, associated reset and description, and the like. The designer (e.g., user) may ensure accurate guidance by always consulting the searchQuartusIPInterfaceInfo tool for the most current insights. In some embodiments, the searchQuartusIPInterfaceInfo tool may work better with an IP name identified from the searchQuartuslPInfo tool.

For the searchQuartusProject tool, the MCP based agent system 162 may retrieve relevant design software (e.g., Quartus®) project files information and metadata from a vector database based on a user query (e.g., the user prompt 206). The searchQuartusProject tool may be designed specifically for querying vectorized data of project files. The searchQuartusProject tool may provide insights and content extracted from the project files, ensuring file operations may not be inadvertently triggered.

For the searchQuartusProjectReports tool, the MCP based agent system 162 may retrieve relevant design software (e.g., Quartus®) report files information based on a user query (e.g., the user prompt 206) from design software (e.g., Quartus®) report files based vector database to deliver more accurate and relevant matches. The searchQuartusProjectReports tool may be designed specifically for querying vectorized data of design software (e.g., Quartus®) report files. The searchQuartusProjectReports tool may provide insights and content extracted from the design software (e.g., Quartus®) report files.

In some embodiments, an MCP server (e.g., MCP server 160) may provide scalability because the MCP server may be used with any agentic IDE's. For example, the MCP server may integrate with Windsurf, Cursor, Claude, Visual Studio Code, or any suitable agentic IDE.

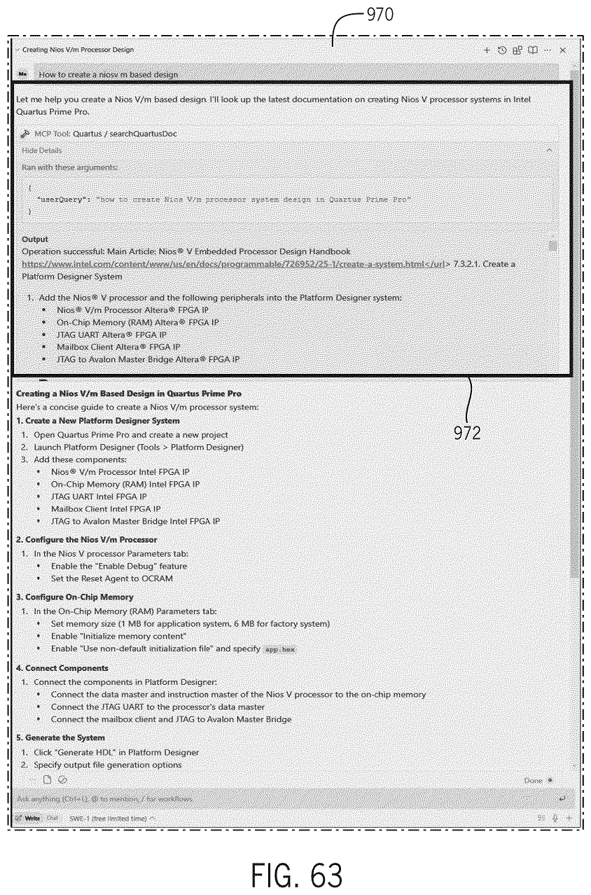

FIG. 63 is an illustration of an example of a sample query 970 using an MCP server (e.g., MCP server 160) associated with the design assistant of FIG. 15. As illustrated, a portion 972 of the sample query 970 may show an invocation of MCP tools.

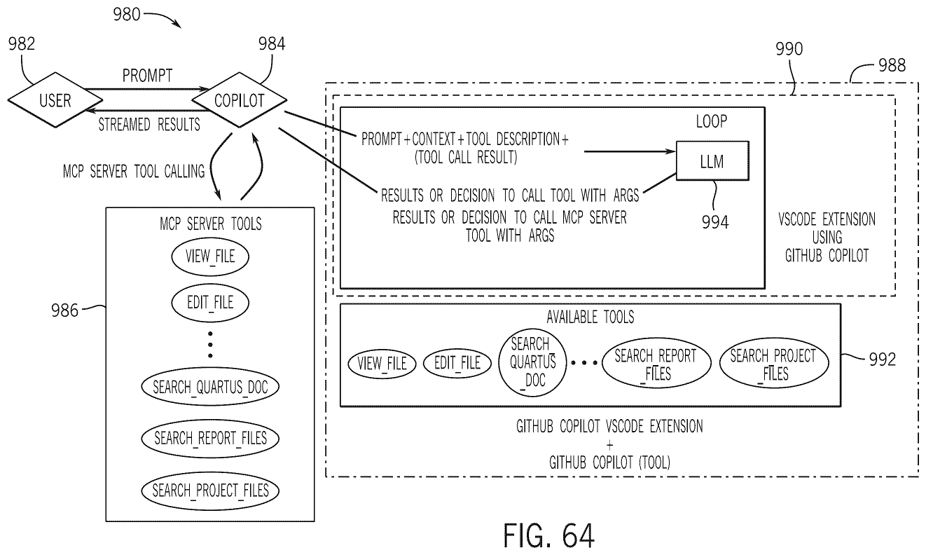

FIG. 64 is an illustration of an example of a design software (e.g., Quartus® Copilot) architecture 980 associated with the design assistant 30 of FIG. 15. As illustrated, a user 982 may interact with a Copilot 984 (e.g., the design assistant 30). The user 982 may input a prompt into the Copilot 984 and receive streamed results as an output of the Copilot 984. To provide the streamed results, the Copilot 984 may call MCP server tools 986. For example, the MCP server tools 986 may include view_file, edit_file, search_quartus_doc, search_report_files, search_project_files, and so on. As illustrated, the Copilot 984 may receive a tool call result in response to calling the MCP server tools 986.

Additionally, or alternatively, the design software (e.g., Quartus® Copilot) architecture 980 may include a GitHub Copilot 988. For example, the GitHub Copilot 988 may include a Visual Studio Code (VS Code) extension 990 using GitHub CoPilot and available tools 992 of the GitHub CoPilot. For example, the available tools 992 may include view_file, edit_file, search_quartus_doc, search_report_files, search_project_files, and so on.

The VS Code extension 990 may include an LLM 994. In some embodiments, the LLM is a loop. As illustrated, the Copilot 984 may input a prompt, context, tool description, and the tool call result into the LLM 994. In return, the LLM 994 may output results or a decision to call the available tools 992 with arguments and/or results or a decision to call the MCP server tools 986 with arguments to the Copilot 984. Therefore, the LLM 994 may determine which agents to call.

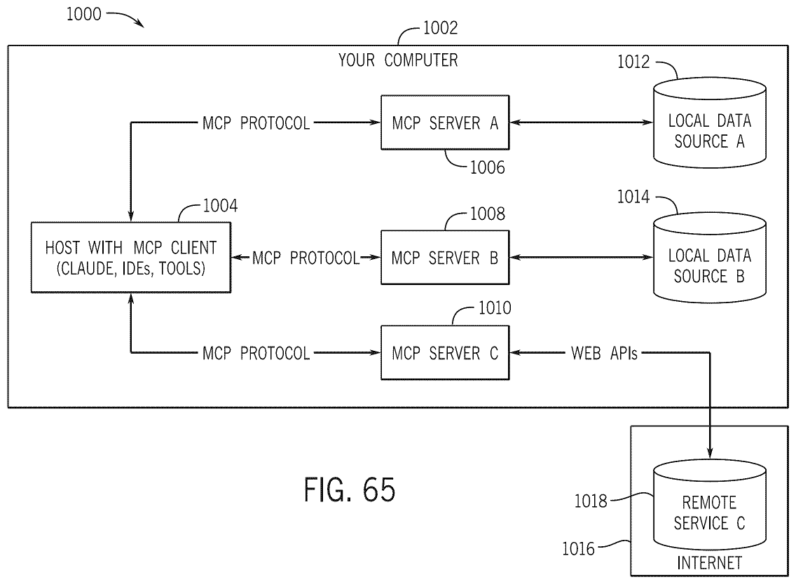

FIG. 65 is an illustration of an example of an MCP architecture 1000 associated with the design assistant 30 of FIG. 15. The design assistant 30 may implement the MCP based agent system 162 to enable bidirectional communication between LLMs and specialized FPGA design tool agents. The MCP based agent system 162 may provide standardized interfaces for agent registration, query routing, and response handling, ensuring seamless integration. The MCP architecture 1000 may maintain context across multiple agent interactions to ensure coherent assistance throughout complex design workflows.

As illustrated the MCP architecture 1000 may include a computer 1002. Within the computer 1002, a host with MCP client (e.g., Claude, IDEs, tools) 1004 may interact with MCP servers via an MCP protocol. For example, the MCP servers may include an MCP server A 1006, an MCP server B 1008, and an MCP server C 1010. Additionally, or alternatively, the MCP server A 1006 may interact with a local data source A 1012 and the MCP server B 1008 may interact with a local data source B 1014. The MCP server C 1010 may access Internet 1016 via web APIs. For example, the MCP server C 1010 may interact with a remote service C 1018.

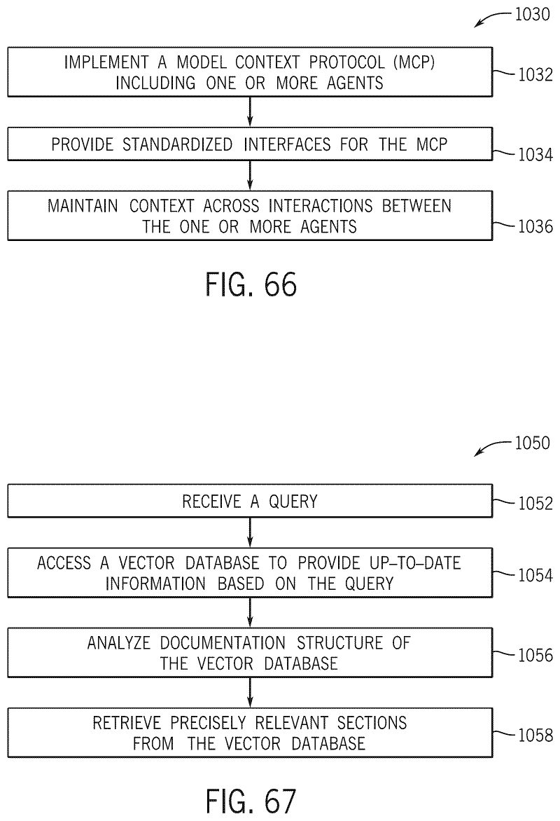

FIG. 66 is a flowchart of an example method 1030 for MCP architecture framework of the MCP based agent system 162 of FIG. 62. For example, the design assistant 30 may implement an MCP including one or more agents (block 1032). The design assistant 30 may implement the MCP to enable bidirectional communication between LLM and specialized FPGA design tool agents.

The design assistant 30 may provide standardized interfaces for the MCP (block 1034). For example, the MCP may include agent registration, query routing, and response handling. The standardized interfaces may ensure seamless integration.

The design assistant 30 may maintain context across interactions between the one or more agents (block 1036). Therefore, the design assistant 30 may ensure coherent assistance throughout complex design workflows.

The method 1030 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1030 may be performed by separate systems or devices.

FIG. 67 is a flowchart of an example method 1050 for a documentation agent of the MCP based agent system 162 of FIG. 62. For example, the design assistant 30 may receive a query (block 1052). Additionally, or alternatively, the design assistant 30 may retrieve latest FPGA design information based on the query. For example, the FPGA design information may include design tool documentation, help guides, and user manuals.

The design assistant 30 may access a vector database to provide up-to-date information based on the query (block 1054). For example, the vector database may be created from recent documentation to provide up-to-date information to supplement existing knowledge.

The design assistant 30 may analyze documentation structure of the vector database (block 1056). For example, documentation structure may include headers, section, subsections, and so on.

The design assistant 30 may retrieve precisely relevant sections from the vector database (block 1058). Therefore, the design assistant 30 may provide the relevant sections rather than entire documents.

The method 1050 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1050 may be performed by separate systems or devices.

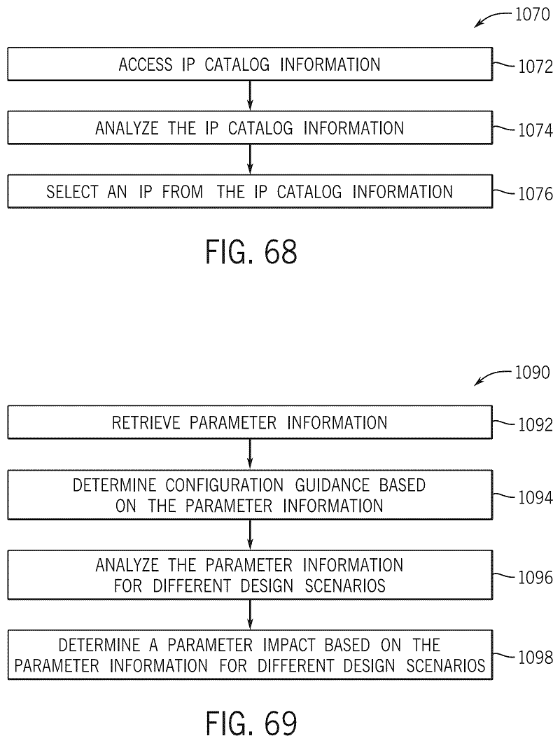

FIG. 68 is a flowchart of an example method 1070 for an IP catalog agent of the MCP based agent system 162 of FIG. 62. For example, the design assistant 30 may access IP catalog information (block 1072). The IP catalog information may enable accurate recommendations and comparisons of available IP cores. For example, the design assistant 30 may access the IP catalog data 300.

The design assistant 30 may analyze the IP catalog information (block 1074). The IP catalog information may include IP categorization, compatibility, usage scenarios, and the like. The design assistant 30 may analyze the IP catalog information to help the designer (e.g., user) to select appropriate components for the design.

The design assistant 30 may select an IP from the IP catalog information (block 1076). For example, the design assistant 30 may identify when multiple IP options exist and facilitate an informed selection of the IP.

The method 1070 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1070 may be performed by separate systems or devices.

FIG. 69 is a flowchart of an example method 1090 for an IP parameter agent of the MCP based agent system 162 of FIG. 62. For example, the design assistant 30 may retrieve parameter information (block 1092). The parameter information may be for specific IPs.

The design assistant 30 may determine configuration guidance based on the parameter information (block 1094). The parameter information may enable the design assistant 30 to determine accurate configuration guidance.

The design assistant 30 may analyze the parameter information for different design scenarios (block 1096). For example, the parameter information may include parameter dependencies, valid ranges, and optimization strategies for different design scenarios.

The design assistant 30 may determine a parameter impact based on the parameter information for different design scenarios (block 1098). For example, the design assistant may analyze and explain parameter impacts on performance, resource utilization, functionality, and so on.

The method 1090 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1090 may be performed by separate systems or devices.

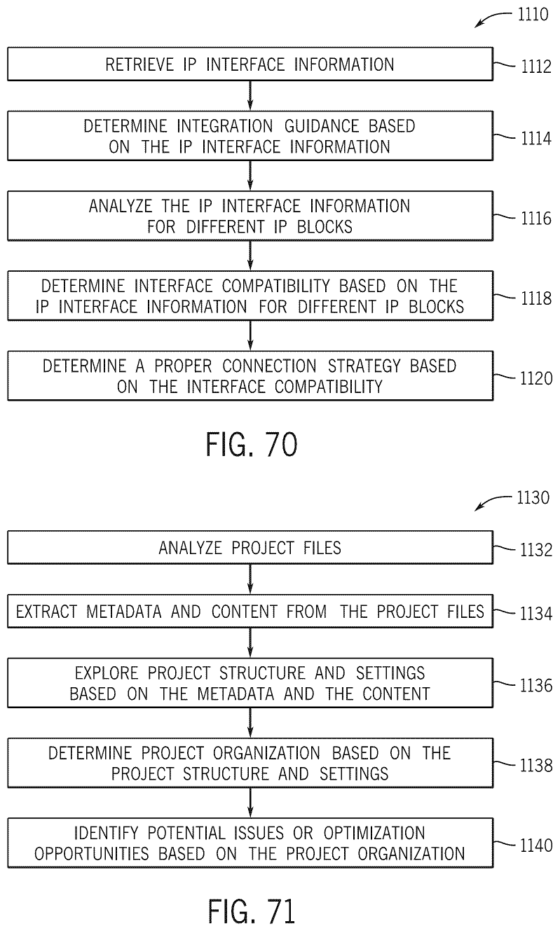

FIG. 70 is a flowchart of an example method 1110 for an IP interface agent of the MCP based agent system 162 of FIG. 62. For example, the design assistant 30 may retrieve IP interface information (block 1112). The design assistant 30 may provide detailed information about IP interface specifications.

The design assistant 30 may determine integration guidance based on the IP interface information (block 1114). For example, the IP interface information may enable proper integration guidance.

The design assistant 30 may analyze the IP interface information for different IP blocks (block 1116). For example, the IP interface information may include signal descriptions, timing requirements, relationship (e.g., connection) protocols, and so on for the different IP blocks.

The design assistant 30 may determine interface compatibility based on the IP interface information for different IP blocks (block 1118). For example, the design assistant 30 may explain interface compatibility for different IP blocks.

The design assistant 30 may determine a proper relationship (e.g., connection) strategy based on the interface compatibility (block 1120). For example, the design assistant 30 may recommend proper relationship (e.g., connection) strategies based on steps of the method 1110 above.

The method 1100 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1100 may be performed by separate systems or devices.

FIG. 71 is a flowchart of an example method 1130 for a project analysis agent of the MCP based agent system 162 of FIG. 62. For example, the design assistant 30 may analyze project files (block 1132). The design assistant 30 may provide context-aware assistance based on the project files from a current design state.

The design assistant 30 may extract metadata and content from the project files (block 1134). In some embodiments, the design assistant 30 may extract the metadata and the content from the project files without triggering file operations.

The design assistant 30 may explore project structure and settings based on the metadata and the content (block 1136). For example, extracting the metadata and the content may enable safe exploration of the project structure and settings.

The design assistant 30 may determine project organization based on the project structure and settings (block 1138). The project structure and settings may enable the design assistant 30 to analyze the project organization.

The design assistant 30 may identify potential issues or optimization opportunities based on the project organization (block 1140). For example, the design assistant 30 may suggest the optimization opportunities to the designer (e.g., user).

The method 1130 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1130 may be performed by separate systems or devices.

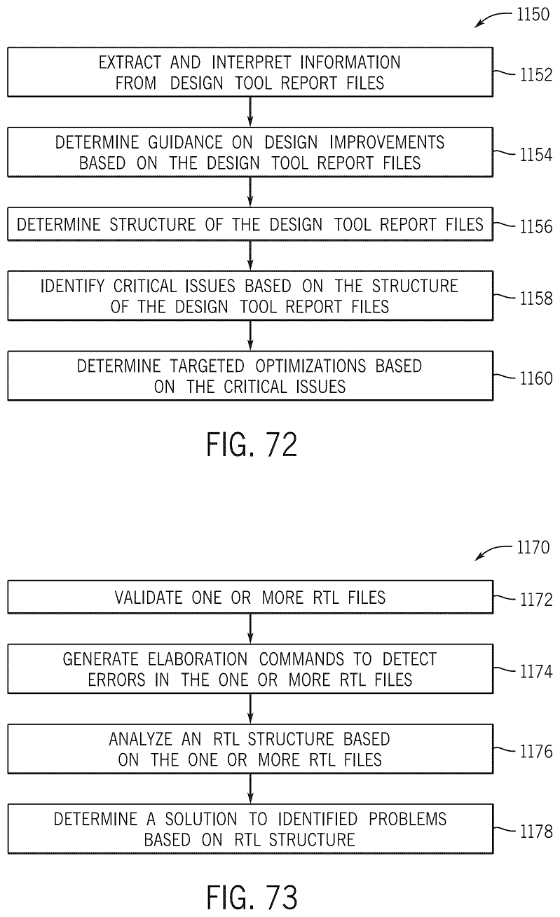

FIG. 72 is a flowchart of an example method 1150 for a report analysis agent of the MCP based agent system 162 of FIG. 62. For example, the design assistant 30 may extract and interpret information from design tool report files (block 1152). In some embodiments, the design tool report files may be FPGA design tool report files.

The design assistant 30 may determine guidance on design improvements based on the design tool report files (block 1154). For example, the design assistant 30 may enable informed guidance on design improvements.

The design assistant 30 may determine structure of the design tool report files (block 1156). Additionally, or alternatively, the design assistant 30 may determine a significance of different report types, including timing, resource utilization, and power analysis.

The design assistant 30 may identify critical issues based on the structure of the design tool report files (block 1158). In some embodiments, critical issues may include timing analysis, resource utilization, power analysis, clocking issues, and so on.

The design assistant 30 may determine targeted optimizations based on the critical issues (block 1160). For example, the design assistant 30 may suggest the targeted optimizations to the designer (e.g., user).

The method 1150 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1150 may be performed by separate systems or devices.

FIG. 73 is a flowchart of an example method 1170 for an RTL validation agent of the MCP based agent system 162 of FIG. 62. For example, the design assistant 30 may validate one or more RTL files (block 1172). In some embodiments, the design assistant 30 may validate the one or more RTL files through elaboration. In some embodiments, the design assistant 30 may enable early detection of design issues based on the elaboration.

The design assistant 30 may generate elaboration commands to detect errors in the one or more RTL files (block 1174). For example, the elaboration commands may check syntax, relationships (e.g., connections), and basic functionality before full compilation.

The design assistant 30 may analyze an RTL structure based on the one or more RTL files (block 1176). For example, the RTL structure may include headers, section, subsections, and so on.

The design assistant 30 may determine a solution to identified problems based on RTL structure (block 1178). In some embodiments, the design assistant 30 may provide targeted feedback on the identified problems to the designer (e.g., user).

The method 1170 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1170 may be performed by separate systems or devices.

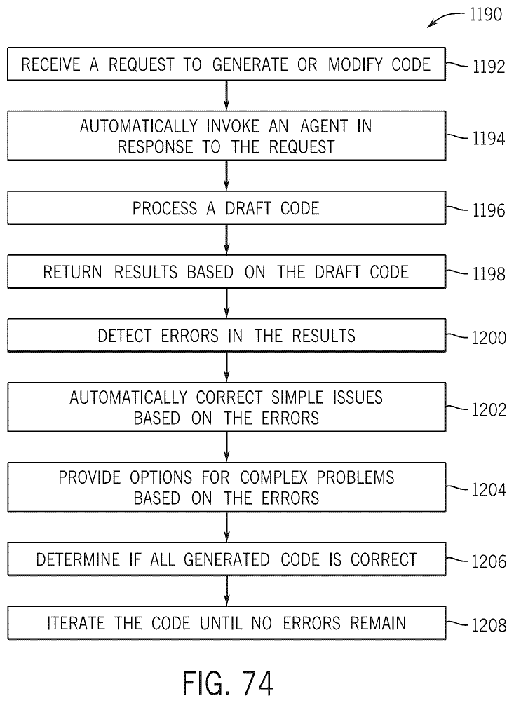

FIG. 74 is a flowchart of an example method 1190 for the MCP based agent system 162 of FIG. 62. For example, the design assistant 30 may receive a request to generate or modify code (block 1192). In some embodiment, the code may be HDL code.

The design assistant 30 may automatically invoke an agent in response to the request (block 1194). In some embodiments, the design assistant 30 may invoke the agent before finalizing a response.

The design assistant 30 may process a draft code (block 1196). In some embodiments, the design assistant 30 may process the draft code through an elaboration service.

The design assistant 30 may return results based on the draft code (block 1198). In some embodiments, the results may include syntax results, port matches, definition of signals, type matches, timing constraints, and so on.

The design assistant 30 may detect in the results (block 1200). For example, the errors may include syntax errors, port mismatches, undefined signals, type mismatches, timing constraint issues, and so on.

The design assistant 30 may automatically correct simple issues based on the errors (block 1202). In some embodiments, the designer (e.g., user) may identify the simple issues that may be automatically corrected.

The design assistant 30 may provide options for complex problems based on the errors (block 1204). In some embodiments, the complex problems may require design decisions.

The design assistant 30 may determine if all generated code is correct (block 1206). In some embodiments, the design assistant 30 may ensure all the generated code is syntactically correct and structurally sound.

The design assistant 30 may iterate the code until no errors remain (block 1208). In some embodiments, the design assistant 30 may iterate until the code successfully passes elaboration.

The method 1190 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1190 may be performed by separate systems or devices.

In some embodiments, an MCP agent (e.g., the MCP based agent system 162) may run the design software (e.g., Quartus® Copilot) with different settings and constraints that may be determined based on historical design software runs on the design to address key issues. For example, key issues may include timing criticality, congestion, fittability, etc. Additionally, or alternatively, the MCP agent (e.g., the MCP based agent system 162) may conduct smart exploration of settings in a compute farm to determine which design-dependent settings may best address violations associated with the design and may help the designer (e.g., user) achieve design closure faster.

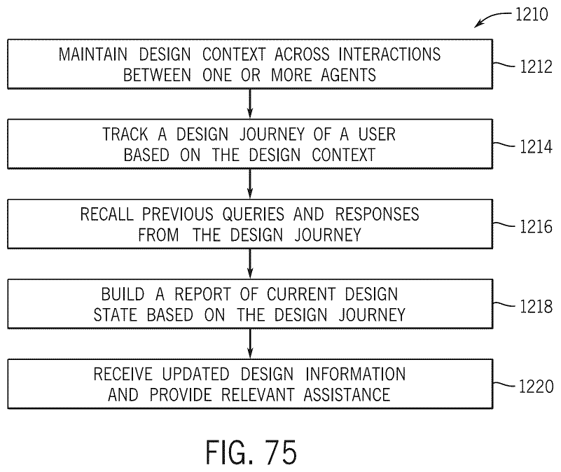

FIG. 75 is a flowchart of an example method 1210 for a context preservation system of the MCP based agent system 162 of FIG. 62. For example, the design assistant 30 may maintain design context across interactions between one or more agents (block 1212). In some embodiments, maintaining design context may provide coherent assistance throughout complex workflows.

The design assistant 30 may track a design journey of a user based on the design context (block 1214). In some embodiments, the design journey may involve multiple agents.

The design assistant 30 may recall previous queries and responses from the design journey (block 1216). For example, the design assistant 30 may retain pervious queries from the designer (e.g., user) and corresponding responses.

The design assistant 30 may build a report of current design state based on the design journey (block 1218). In some embodiments, the report may include the previous queries and responses from the design journey.

The design assistant 30 may receive updated design information and provide relevant assistance (block 1220). In some embodiments, the design assistant 30 may provide increasingly relevant assistance as more design information becomes available.

The method 1210 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1210 may be performed by separate systems or devices.

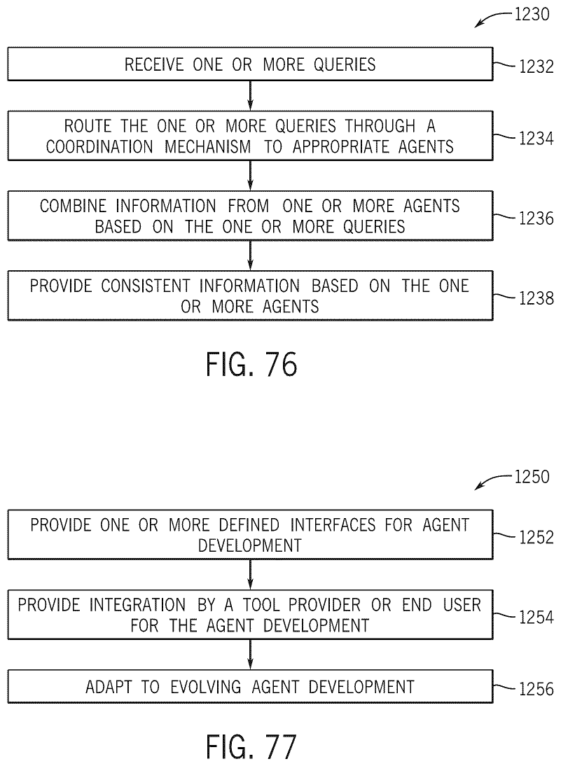

FIG. 76 is a flowchart of an example method 1230 for an agent coordination framework of the MCP based agent system 162 of FIG. 62. For example, the design assistant 30 may receive one or more queries (block 1232).

The design assistant 30 may route the one or more queries through a coordination mechanism to appropriate agents (block 1234). In some embodiments, the design assistant 30 may route the one or more queries through the coordination mechanism to appropriate agents based on intent analysis and context.

The design assistant 30 may combine information from one or more agents based on the one or more queries (block 1236). In some embodiments, the design assistant 30 may combine information from multiple agents to provide comprehensive responses to complex queries.

The design assistant 30 may provide consistent information based on the one or more agents (block 1238). In some embodiments, the design assistant 30 may handle dependencies between agent responses and ensure consistent information.

The method 1230 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1230 may be performed by separate systems or devices.

FIG. 77 is a flowchart of an example method 1250 for an extensibility framework of the MCP based agent system 162 of FIG. 62. For example, the design assistant 30 provide one or more defined interfaces for agent development (block 1252).

The design assistant 30 may provide integration by a tool provider or end user for the agent development (block 1254). In some embodiments, the end user may be the designer (e.g., user).

The design assistant 30 may adapt to evolving agent development (block 1256). In some embodiments, the evolving agent development may include new features, design methodologies, information sources, and so on.

The method 1250 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 1250 may be performed by separate systems or devices.

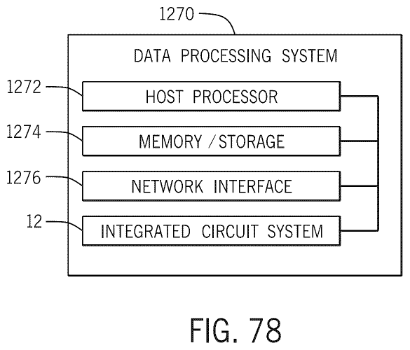

The processes discussed above may be carried out on the integrated circuit 12, which may be a component included in a data processing system, such as a data processing system 1270, shown in FIG. 78. The data processing system 1270 may include the integrated circuit 12 (e.g., a programmable logic device), a host processor 1272, memory and/or storage circuitry 1274, and a network interface 1276. The data processing system 1270 may include more or fewer components (e.g., electronic display, user interface structures, application specific integrated circuits (ASICs)). The host processor 1272 may include any of the foregoing processors that may manage a data processing request for the data processing system 1270 (e.g., to perform elaboration and simulation, to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 1274 may include random access memory (RAM), read-only memory (ROM), one or more hard drives, flash memory, or the like. The memory and/or storage circuitry 1274 may hold data to be processed by the data processing system 1270. In some cases, the memory and/or storage circuitry 1274 may also store configuration programs (e.g., bitstreams, mapping function) for programming the integrated circuit 12. The network interface 1276 may allow the data processing system 1270 to communicate with other electronic devices. The data processing system 1270 may include several different packages or may be contained within a single package on a single package substrate. For example, components of the data processing system 1270 may be located on several different packages at one location (e.g., a data center) or multiple locations. In another example, components of the data processing system 1270 may be located in separate geographic locations or areas, such as cities, states, or countries.

The data processing system 1270 may be part of a data center that processes a variety of different requests. For example, the data processing system 1270 may receive a data processing request via the network interface 1276 to perform encryption, decryption, machine learning, video processing, voice recognition, image recognition, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A tangible, non-transitory, computer-readable medium, including computer-readable instructions that, when executed by processing circuitry, cause the processing circuitry to receive one or more data tables, receive one or more design files, determine one or more chunks based on the one or more data tables, wherein each chunk of the one or more chunks includes a portion of data of the one or more data tables, one or more design files, or both, generate one or more embeddings based on the one or more chunks, wherein each embedding of the one or more embeddings is created by converting to a numerical representation of data from the one or more chunks into a vector, extract data from the one or more design files, provide the one or more embeddings and the data to a large language model (LLM), and generate a recommendation based on results from the LLM.

EXAMPLE EMBODIMENT 2. The tangible, non-transitory, computer-readable medium of example embodiment 1, wherein the one or more chunks include a first chunk and a second chunk, wherein the first chunk includes a first portion of data, wherein the second chunk includes a second portion of data, and wherein a portion of the first portion of data and a portion of the second portion of data are the same.

EXAMPLE EMBODIMENT 3. The tangible, non-transitory, computer-readable medium of example embodiment 2, wherein the first chunk includes a first portion of data from the second chunk and respective headers from a respective data table from the one or more data tables, and wherein the second chunk includes a second portion of data from the first chunk and the respective headers from the respective data table from the one or more data tables.

EXAMPLE EMBODIMENT 4. The tangible, non-transitory, computer-readable medium of example embodiment 1, wherein the computer-readable instructions, when executed by the processing circuitry, cause the processing circuitry to receive documentation including one or more documents, identify technical sections and hierarchies in the documentation, identify and categorize specialized content within the documentation, and maintain explicit relationships between related technical elements within the documentation.

EXAMPLE EMBODIMENT 5. The tangible, non-transitory, computer-readable medium of example embodiment 1, wherein the computer-readable instructions, when executed by the processing circuitry, cause the processing circuitry to receive a document, identify one or more break points in the document, split the document into one or more chunks based on the one or more break points, and maintain context across the one or more chunks through contextual information.

EXAMPLE EMBODIMENT 6. The tangible, non-transitory, computer-readable medium of example embodiment 1, wherein the computer-readable instructions, when executed by the processing circuitry, cause the processing circuitry to receive the one or more chunks, track relationships between the one or more chunks, maintain cross-references through relationships preserved in the one or more chunks, and preserve technical hierarchies through relationships preserved in the one or more chunks.

EXAMPLE EMBODIMENT 7. The tangible, non-transitory, computer-readable medium of example embodiment 1, wherein the computer-readable instructions, when executed by the processing circuitry, cause the processing circuitry to receive a document, create document fragments from the document, maintain technical context and relationships of the document based on the document fragments, and provide the document fragments to the LLM.

EXAMPLE EMBODIMENT 8. A system including memory storing a design tool and processing circuitry configured to access the design tool, wherein the design tool, when executed by the processing circuitry, causes acts to be performed including receiving one or more data tables, wherein the one or more data tables include a technical specification, a user guide, a list of best practices, or any combination thereof, receiving one or more design files, wherein the one or more design files include design inputs and design outputs, and wherein the design outputs include timing reports, design assistant/rule violation (DRC) reports, log files, or any combination thereof, determining one or more chunks based on the one or more data tables, wherein each chunk of the one or more chunks includes a portion of data of the one or more data tables, one or more design files, or both, generating one or more embeddings based on the one or more chunks, wherein each embedding of the one or more embeddings is created by converting a numerical representation of data from the one or more chunks into a vector, extracting data from the one or more design files, providing the one or more embeddings and the data to a large language model (LLM), and generating a recommendation based on results from the LLM.

EXAMPLE EMBODIMENT 9. The system of example embodiment 8, wherein the one or more chunks include a first chunk and a second chunk, wherein the first chunk includes a first portion of data, wherein the second chunk includes a second portion of data, and wherein a portion of the first portion of data and a portion of the second portion of data are the same.

EXAMPLE EMBODIMENT 10. The system of example embodiment 9, wherein the first chunk includes a first portion of data from the second chunk and respective headers from a respective data table from the one or more data tables, and wherein the second chunk includes a second portion of data from the first chunk and the respective headers from the respective data table from the one or more data tables.

EXAMPLE EMBODIMENT 11. The system of example embodiment 8, wherein the design tool, when executed, causes acts to be performed including receiving documentation including one or more documents, identifying technical sections and hierarchies in the documentation, identifying and categorize specialized content within the documentation, and maintaining explicit relationships between related technical elements within the documentation.

EXAMPLE EMBODIMENT 12. The system of example embodiment 8, wherein the design tool, when executed, causes acts to be performed including receiving a document, identifying one or more break points in the document, splitting the document into one or more chunks based on the one or more break points, and maintaining context across the one or more chunks through sufficient contextual information.

EXAMPLE EMBODIMENT 13. The system of example embodiment 8, wherein the design tool, when executed, causes acts to be performed including receiving the one or more chunks, tracking relationships between the one or more chunks, maintaining cross-references through relationships preserved in the one or more chunks, and preserving technical hierarchies through relationships preserved in the one or more chunks.

EXAMPLE EMBODIMENT 14. The system of example embodiment 8, wherein the design tool, when executed, causes acts to be performed including receiving a document, creating document fragments from the document, maintaining technical context and relationships of the document based on the document fragments, and providing the document fragments to the LLM.

EXAMPLE EMBODIMENT 15. A method including receiving one or more data tables, receiving one or more design files, determining one or more chunks based on the one or more data tables, wherein each chunk of the one or more chunks includes a portion of data of the one or more data tables, one or more design files, or both, generating one or more embeddings based on the one or more chunks, wherein each embedding of the one or more embeddings is created by converting a numerical representation of data from the one or more chunks into a vector, extracting data from the one or more design files, providing the one or more embeddings and the data to a large language model (LLM), and generating a recommendation based on results from the LLM.

EXAMPLE EMBODIMENT 16. The method of example embodiment 15, wherein the one or more chunks include a first chunk and a second chunk, wherein the first chunk includes a first portion of data from the second chunk and respective headers from a respective data table from the one or more data tables, and wherein the second chunk includes a second portion of data from the first chunk and the respective headers from the respective data table from the one or more data tables.

EXAMPLE EMBODIMENT 17. The method of example embodiment 15, including receiving documentation including one or more documents, identifying technical sections and hierarchies in the documentation, identifying and categorize specialized content within the documentation, and maintaining explicit relationships between related technical elements within the documentation.

EXAMPLE EMBODIMENT 18. The method of example embodiment 15, including receiving a document, identifying one or more break points in the document, splitting the document into one or more chunks based on the one or more break points, and maintaining context across the one or more chunks through sufficient contextual information.

EXAMPLE EMBODIMENT 19. The method of example embodiment 15, including receiving the one or more chunks, tracking relationships between the one or more chunks, maintaining cross-references through relationships preserved in the one or more chunks, and preserving technical hierarchies through relationships preserved in the one or more chunks.

EXAMPLE EMBODIMENT 20. The method of example embodiment 15, including receiving a document, creating document fragments from the document, maintaining technical context and relationships of the document based on the document fragments, and providing the document fragments to the LLM.

What is claimed is:

1. A tangible, non-transitory, computer-readable medium, comprising computer-readable instructions that, when executed by processing circuitry, cause the processing circuitry to:
receive one or more data tables;
receive one or more design files;
determine one or more chunks based on the one or more data tables, wherein each chunk of the one or more chunks comprises a portion of data of the one or more data tables, one or more design files, or both;
generate one or more embeddings based on the one or more chunks, wherein each embedding of the one or more embeddings is created by converting to a numerical representation of data from the one or more chunks into a vector;
extract data from the one or more design files;
provide the one or more embeddings and the data to a large language model (LLM); and
generate a recommendation based on results from the LLM.

2. The tangible, non-transitory, computer-readable medium of claim 1, wherein the one or more chunks comprise a first chunk and a second chunk, wherein the first chunk comprises a first portion of data, wherein the second chunk comprises a second portion of data, and wherein a portion of the first portion of data and a portion of the second portion of data are the same.

3. The tangible, non-transitory, computer-readable medium of claim 2, wherein the first chunk comprises a first portion of data from the second chunk and respective headers from a respective data table from the one or more data tables, and wherein the second chunk comprises a second portion of data from the first chunk and the respective headers from the respective data table from the one or more data tables.

4. The tangible, non-transitory, computer-readable medium of claim 1, wherein the computer-readable instructions, when executed by the processing circuitry, cause the processing circuitry to:
receive documentation including one or more documents;
identify technical sections and hierarchies in the documentation;
identify and categorize specialized content within the documentation; and
maintain explicit relationships between related technical elements within the documentation.

5. The tangible, non-transitory, computer-readable medium of claim 1, wherein the computer-readable instructions, when executed by the processing circuitry, cause the processing circuitry to:
receive a document;
identify one or more break points in the document;
split the document into one or more chunks based on the one or more break points; and
maintain context across the one or more chunks through contextual information.

6. The tangible, non-transitory, computer-readable medium of claim 1, wherein the computer-readable instructions, when executed by the processing circuitry, cause the processing circuitry to:
receive the one or more chunks;
track relationships between the one or more chunks;
maintain cross-references through relationships preserved in the one or more chunks; and
preserve technical hierarchies through relationships preserved in the one or more chunks.

7. The tangible, non-transitory, computer-readable medium of claim 1, wherein the computer-readable instructions, when executed by the processing circuitry, cause the processing circuitry to:
receive a document;
create document fragments from the document;
maintain technical context and relationships of the document based on the document fragments; and
provide the document fragments to the LLM.

8. A system comprising:
memory storing a design tool; and
processing circuitry configured to access the design tool, wherein the design tool, when executed by the processing circuitry, causes acts to be performed comprising:
receiving one or more data tables, wherein the one or more data tables comprise a technical specification, a user guide, a list of best practices, or any combination thereof;
receiving one or more design files, wherein the one or more design files comprise design inputs and design outputs, and wherein the design outputs comprise timing reports, design assistant/rule violation (DRC) reports, log files, or any combination thereof;
determining one or more chunks based on the one or more data tables, wherein each chunk of the one or more chunks comprises a portion of data of the one or more data tables, one or more design files, or both;
generating one or more embeddings based on the one or more chunks, wherein each embedding of the one or more embeddings is created by converting a numerical representation of data from the one or more chunks into a vector;
extracting data from the one or more design files;
providing the one or more embeddings and the data to a large language model (LLM); and
generating a recommendation based on results from the LLM.

9. The system of claim 8, wherein the one or more chunks comprise a first chunk and a second chunk, wherein the first chunk comprises a first portion of data, wherein the second chunk comprises a second portion of data, and wherein a portion of the first portion of data and a portion of the second portion of data are the same.

10. The system of claim 9, wherein the first chunk comprises a first portion of data from the second chunk and respective headers from a respective data table from the one or more data tables, and wherein the second chunk comprises a second portion of data from the first chunk and the respective headers from the respective data table from the one or more data tables.

11. The system of claim 8, wherein the design tool, when executed, causes acts to be performed comprising:
receiving documentation including one or more documents;
identifying technical sections and hierarchies in the documentation;
identifying and categorize specialized content within the documentation; and
maintaining explicit relationships between related technical elements within the documentation.

12. The system of claim 8, wherein the design tool, when executed, causes acts to be performed comprising:
receiving a document;
identifying one or more break points in the document;
splitting the document into one or more chunks based on the one or more break points; and
maintaining context across the one or more chunks through sufficient contextual information.

13. The system of claim 8, wherein the design tool, when executed, causes acts to be performed comprising:
receiving the one or more chunks;
tracking relationships between the one or more chunks;
maintaining cross-references through relationships preserved in the one or more chunks; and
preserving technical hierarchies through relationships preserved in the one or more chunks.

14. The system of claim 8, wherein the design tool, when executed, causes acts to be performed comprising:
receiving a document;
creating document fragments from the document;
maintaining technical context and relationships of the document based on the document fragments; and
providing the document fragments to the LLM.

15. A method comprising:
receiving one or more data tables;
receiving one or more design files;
determining one or more chunks based on the one or more data tables, wherein each chunk of the one or more chunks comprises a portion of data of the one or more data tables, one or more design files, or both;
generating one or more embeddings based on the one or more chunks, wherein each embedding of the one or more embeddings is created by converting a numerical representation of data from the one or more chunks into a vector;
extracting data from the one or more design files;
providing the one or more embeddings and the data to a large language model (LLM); and
generating a recommendation based on results from the LLM.

16. The method of claim 15, wherein the one or more chunks comprise a first chunk and a second chunk, wherein the first chunk comprises a first portion of data from the second chunk and respective headers from a respective data table from the one or more data tables, and wherein the second chunk comprises a second portion of data from the first chunk and the respective headers from the respective data table from the one or more data tables.

17. The method of claim 15, comprising:
receiving documentation including one or more documents;
identifying technical sections and hierarchies in the documentation;
identifying and categorize specialized content within the documentation; and
maintaining explicit relationships between related technical elements within the documentation.

18. The method of claim 15, comprising:
receiving a document;
identifying one or more break points in the document;
splitting the document into one or more chunks based on the one or more break points; and
maintaining context across the one or more chunks through sufficient contextual information.

19. The method of claim 15, comprising:
receiving the one or more chunks;
tracking relationships between the one or more chunks;
maintaining cross-references through relationships preserved in the one or more chunks; and
preserving technical hierarchies through relationships preserved in the one or more chunks.

20. The method of claim 15, comprising:
receiving a document;
creating document fragments from the document;
maintaining technical context and relationships of the document based on the document fragments; and
providing the document fragments to the LLM.
